(19) United States
(12) Patent Application Publication
(10) Pub. No.: US 2024/0088136 A1
(43) Pub. Date: Mar. 14, 2024

(54) TRANSISTOR DEVICES WITH EXTENDED DRAIN

(71) Applicant: Intel Corporation, Santa Clara, CA (US)

(72) Inventors: Ayan Kar, Portland, OR (US); Nicholas A. Thomson, Hillsboro, OR (US); Kalyan C. Kolluru, Portland, OR (US); Benjamin Orr, Beaverton, OR (US)

(73) Assignee: Intel Corporation, Santa Clara, CA (US)

(21) Appl. No.: 17/943,557

(22) Filed: Sep. 13, 2022

(51) Int. Cl. H01L 27/02

(52) U.S. Cl. CPC H01L 27/027

(57) ABSTRACT

An integrated circuit structure includes a sub-fin, a source region in contact with a first portion of the sub-fin, and a drain region in contact with a second portion of the sub-fin. A body including semiconductor material is above the sub-fin, where the body extends laterally between the source region and the drain region. A gate structure is on the body and includes (i) a gate electrode, and (ii) a gate dielectric between the gate electrode and the body. In an example, a first distance between the drain region and the gate electrode is at least two times a second distance between the source region and the gate electrode, where the first and second distances are measured in a same horizontal plane that runs in a direction parallel to the body. In an example, the body is a nanoribbon, a nanosheet, a nanowire, or a fin.

### FIELD OF THE DISCLOSURE

The present disclosure relates to integrated circuits, and more particularly, to transistor devices.

### BACKGROUND

During an electrostatic discharge (ESD) event in an integrated circuit (IC), an input/output (I/O) pad may experience high voltage. Various ESD protection devices maybe used, e.g., to protect the IC from failure during the ESD event. For example, transistors and/or diodes may be used as an EDS protection device in high-speed I/O designs, where the high voltage is grounded through these devices. Designing ESD protection devices involves many non-trivial issues.

### BRIEF DESCRIPTION OF THE DRAWINGS

FIGS. 1A-1D are cross-sectional views of an integrated circuit structure that includes (i) a sub-fin, (ii) a source region in contact with a first portion of the sub-fin, (iii) a drain region in contact with a second portion of the sub-fin, (iv) one or more bodies comprising semiconductor material above the sub-fin, the one or more bodies extending laterally between the source region and the drain region, and (v) a gate structure on the one or more bodies, the gate structure comprising a gate electrode, and gate dielectric between the gate electrode and the one or more bodies, wherein a distance w2 between the drain region and the gate electrode is at least twice a distance w1 between the source region and the gate electrode, wherein the distances w1, w2 are measured in a same horizontal plane that runs in a direction parallel to the one or more bodies, in accordance with an embodiment of the present disclosure.

FIGS. 2A-2C illustrate example applications of the structure of FIGS. 1A-1D, in accordance with an embodiment of the present disclosure.

FIGS. 3A-3D are cross-sectional views of an integrated circuit structure that includes (i) a sub-fin, (ii) a source region in contact with a first portion of the sub-fin, (iii) a drain region in contact with a second portion of the sub-fin, wherein the drain region is U-shaped and comprises a first vertical end portion, a second vertical end portion, and an intermediate horizontal portion between the two end portions, in accordance with an embodiment of the present disclosure.

FIG. 4 illustrates a flowchart depicting a method of forming an integrated circuit structure (such as the integrated circuit structure of FIGS. 1A-1D), in accordance with an embodiment of the present disclosure.

FIGS. 5A, 5B, 5C, 5D, 5E, 5F, 5G, and 511 collectively illustrate cross-sectional views of an integrated circuit structure in various stages of processing in the methodology of FIG. 4, in accordance with an embodiment of the present disclosure.

FIG. 6 illustrates a flowchart depicting a method of forming another integrated circuit structure (such as the integrated circuit structure of FIGS. 3A-3D), in accordance with an embodiment of the present disclosure.

FIGS. 7A, 7B, 7C, 7D, 7E, 7F, 7G, and 711 collectively illustrate cross-sectional views of an integrated circuit structure in various stages of processing in the methodology of FIG. 6, in accordance with an embodiment of the present disclosure.

FIG. 8 illustrates a computing system implemented with integrated circuit structures (such as the structures illustrated in FIGS. 1A-3D) formed using the techniques disclosed herein, in accordance with some embodiments of the present disclosure.

As will be appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used. Likewise, while the thickness of a given first layer may appear to be similar in thickness to a second layer, in actuality that first layer may be much thinner or thicker than the second layer; same goes for other layer or feature dimensions.

### DETAILED DESCRIPTION

Integrated circuit structures including transistors having an extended drain region are described. The structures can be use in any number of applications, but are particularly well-suited for ESD protection schemes implemented with transistors. In an example, the effective or functional drain region is physically extended, thereby increasing a resistance of the extended drain region. The drain region may be coupled to an I/O terminal or other node that may experience a high voltage during an ESD event. In an example, the resistance of the extended drain region causes a relatively low voltage (e.g., low compared to the high ESD voltage) to be applied at a junction of the gate structure and the extended drain region, e.g., due to a voltage drop in the extended portion of the drain region, thereby preventing or reducing possibilities of failure of gate dielectric during an ESD event.

In one embodiment, an integrated circuit structure comprises a sub-fin, a source region in contact with a first portion of the sub-fin, a drain region in contact with a second portion of the sub-fin, and a body comprising semiconductor material above the sub-fin. The body extends laterally between the source region and the drain region. A gate structure is on the body and comprises (i) a gate electrode, and (ii) a gate dielectric between the gate electrode and the body. In an example, a first distance between the drain region and the gate electrode is multiple times (such as at least 2×, or at least 3×, or at least 4×, or at least 5×, or at least 6×, or at least 10, or at least 12×, or at least 20×) a second distance between the source region and the gate electrode. The first and second distances are measured in a same horizontal plane that runs in a direction parallel to the body. In an example, from a functional perspective of the structure, the drain region is extended within at least a section of the second portion of the sub-fin, resulting in a voltage drop within at least the section of the second portion of the sub-fin during an ESD event. In an example, this reduces a voltage applied at a drain-gate junction, thereby preventing or reducing possibilities of failure of gate dielectric during the ESD event.

In another embodiment, an integrated circuit structure comprises a sub-fin including (i) a first portion doped with a first type of dopant, and (ii) a second portion doped with a second type of dopant and laterally adjacent to the first portion. The first type of dopant is one of a p-type or an n-type dopant, and wherein the second type of dopant is the other of the p-type or the n-type dopant. A source region is doped with the second type of dopant, where the source region is in contact with the first portion of the sub-fin. A drain region is doped with the second type dopant, where the drain region is in contact with the second portion of the sub-fin that is also doped with the second type of dopant.

In yet another embodiment, a transistor structure circuit structure comprises a sub-fin comprising (i) a first portion comprising p-type dopant, and (ii) a second portion comprising n-type of dopant. A first source or drain region is in contact with the first portion of the sub-fin, and a second source or drain region is in contact with the second portion of the sub-fin. A body comprising semiconductor material extends laterally between the first and second source or drain regions, where the body has a first section and a laterally adjacent second section. In an example, the first section of the body is above the first portion of the sub-fin, and the second section of the body is above the second portion of the sub-fin. In an example, the body is one of a nanoribbon, a nanosheet, a nanowire, or a fin. Numerous configurations and variations will be apparent in light of this disclosure.

### General Overview

As mentioned herein above, there are various non-trivial issues associated with designing ESD protection devices. For example, one or more transistors may be used as an ESD protection device in high-speed I/O designs. For example, a transistor implemented as a ground-gate N-type MOSFET (GGNMOS) may be used as a snapback mode ESD protection device. In such implementations, during an ESD event, high current and/or voltage at the drain of the GGNMOS causes the GGNMOS to snapback and, the transistor begins to shunt the ESD current to ground, protecting the core circuit from the ESD stress. However, in some examples, a GGNMOS device may be susceptible to gate dielectric breakdown, and may fail prematurely during ESD events. For example, the high voltage ESD spike at the drain of the GGNMOS may induce gate dielectric leakage and/or breakdown at the corner region between the drain and the gate dielectric. Adding series ballast resistance at the drain node of a GGNMOS device may help to distribute the ESD current across all legs of the device more uniformly and may further help to reduce the voltage at the drain-gate junction during an ESD event, thereby preventing or reducing possibilities of gate dielectric leakage and/or breakdown. However, adding such an external ballast resistor has the drawback of significantly increasing the layout complexity, footprint size (area), and capacitive coupling.

Accordingly, techniques are provided herein to form a transistor for ESD applications, or another appropriate application in which the transistor experiences high drain-to-source voltage, where a distance between a drain region and a gate structure of the transistor is made relatively large using an appropriate doped portion of a sub-fin that is doped similar to the drain region, e.g., larger than a distance between a source region and the gate structure of the transistor. The large distance effectively adds a resistance between the drain region and the gate structure, e.g., because the doped portion of the sub-fin contributing to the large distance is doped similar to the drain region, and functions as an extension of the drain region. The increase in the effective drain region results in an extended drain region. Accordingly, during an ESD high voltage event, the voltage at the junction of the gate structure and the extended drain region is now reduced (e.g., compared to the high ESD voltage at the original drain region), e.g., due to voltage drop at the extended portion of the drain, thereby preventing or least reducing chances of gate dielectric breakdown due to ESD events.

In an example ESD protection transistor, the source and drain regions are formed on a sub-fin having different portions with different doping schemes. An example described herein assumes the transistor structure to be an n-type transistor, and describes the doping scheme for an NMOS transistor. However, in another example the transistor structure may be a p-type transistor (e.g., PMOS transistor), and the doping scheme may be reversed.

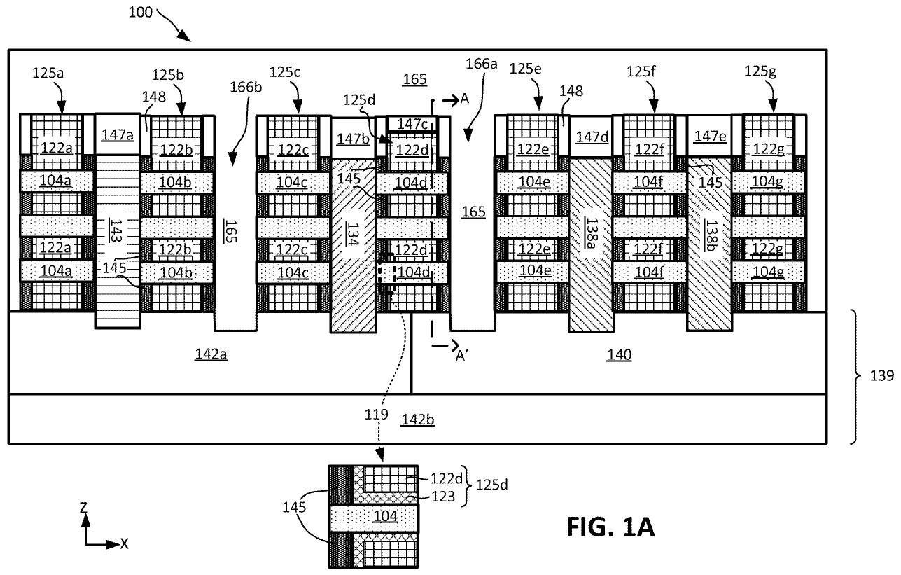

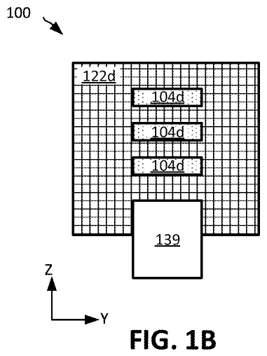

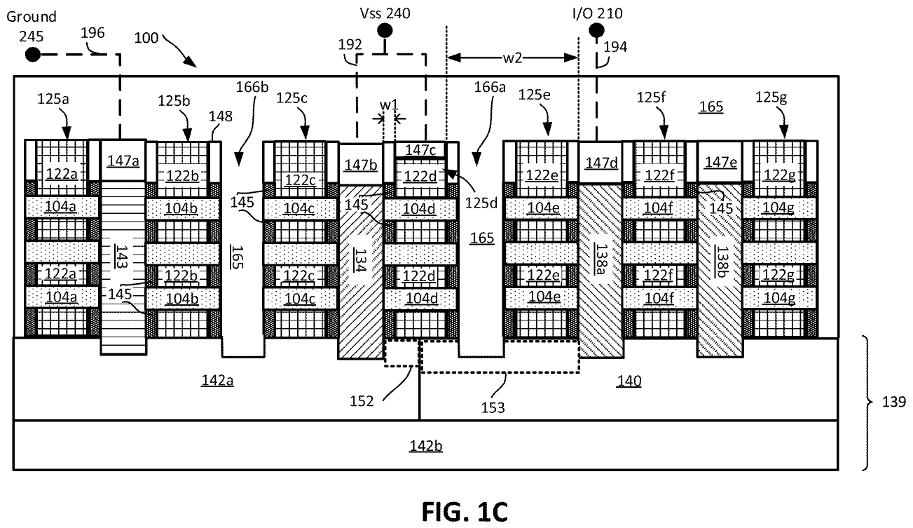

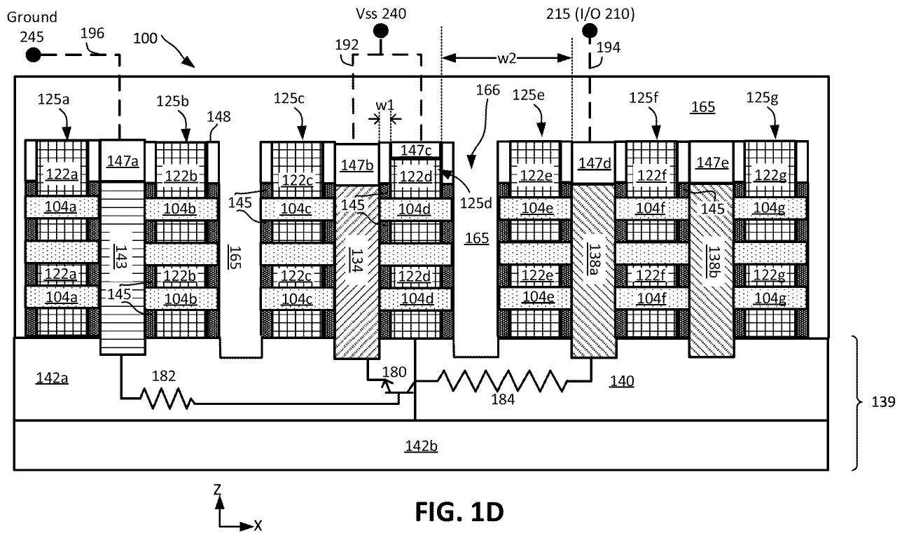

For an NMOS transistor structure, the sub-fin has a first portion having p-type dopant, and a second portion having an n-type dopant. The source and drain regions of the NMOS device have the n-type dopant. The source region is in contact with the first portion of the sub-fin (that has the p-type dopant), and the drain region is in contact with the second portion of the sub-fin (that has the n-type dopant). Because each of the drain region and the second portion of the sub-fin has the same doping type (e.g., n-type dopant), from functional perspective, this effectively extends the drain region to at least a section (e.g., section 153, see FIG. 1C) of the second portion of the sub-fin. Put differently, at least the section of the second portion of the sub-fin acts as an extended drain region, and this section is also referred to herein as “section 153” in accordance with the labelling of FIG. 1C.

In one embodiment, the transistor comprises GAA channel regions, such as nanoribbons. As will be further appreciated in light of this disclosure, reference to nanoribbons is also intended to include other channel regions, such as nanowires or nanosheets, and other such semiconductor bodies around which a gate structure at least in part wraps. To this end, the use of a specific channel region configuration (e.g., nanoribbons or GAA) is not intended to limit the present description to that specific channel configuration. In an example, the description provided herein is readily applicable to devices in which the gate at least partially wrap around the channel region, such as finFET structures having fins as channel regions (e.g., tri-gate and forksheet transistor structures).

In an example, the transistor comprises nanoribbons (or other types of channel regions, such as nanosheets, nanowires, or fins) as channel regions. In general, in GAA transistors, nanoribbons extend laterally from a source region to a drain region. In contrast, in the ESD protection transistor discussed herein, first one or more nanoribbons extend from the source region towards the drain region, second one or more nanoribbons extend from the drain region towards the source region, and a dielectric material structure is laterally between the first one or more nanoribbons and the second one or more nanoribbons. Thus, in an example, there is no continuous nanoribbon extending from the source region and to drain region, and hence, the first and second one or more nanoribbons are non-functional, e.g., they do not contribute to current conduction within the transistor. In an example, the ESD protection transistor is formed laterally adjacent to one or more other transistor structures, such as one or more other nanoribbon transistor structures. Common or same channel region formation processes can be performed across multiple such transistor structures in at least a section of the die. Because of the same channel region formation processes, the nanoribbon channel regions are also formed within the ESD protection transistor, e.g., even though the nanoribbons may not contribute in current conduction. Note that each of the above discussed first one or more nanoribbons has a first section that is above the first portion of the sub-fin, and has a second section that is above the second portion of the sub-fin.

In an example, the current conduction of the ESD protection transistor is through the sub-fin. For example, as discussed herein above, the first one or more nanoribbons extend from the source region towards the drain region, and a gate structure is on the nanoribbons (e.g., wraps around middle portion of individual nanoribbons). This gate structure is also referred herein as a “first gate structure,” to distinguish this gate structure from other gate structures of the ESD protection transistor. In an example, a section of the of the first portion of the sub-fin (e.g., section 152, see FIG. 1C) is below the first one or more nanoribbons, and is partly wrapped by the first gate structure. For example, the first gate structure is on top, front and back of the section of the of the first portion of the sub-fin, where the section is also referred to herein as “section 152”, in accordance with the labelling used in FIG. 1C. Thus, the first gate structure can effectively control current through this section 152, and this section 152 acts as an effective channel region of the transistor.

Note that as discussed herein above, the first one or more nanoribbons, and the first gate structure thereon, are adjacent to the source region. For example, the source region is at a distance w1 from the gate electrode of the first gate structure (see FIG. 1C for the distance w1), where w1 is equal to a width of an inner gate spacer. In contrast, the drain region is a distance w2 from the gate electrode of the first gate structure. For example, the distance w2 is a sum of (i) the second one or more nanoribbons adjacent to the drain region, and (ii) a trench comprising dielectric material that is laterally between the first and second one or more nanoribbons. For example, the section 153 discussed herein above at least in part spans the distance w2, e.g., as illustrated in FIG. 1C herein above.

In an example, the transistor structure is configured as a ground-gate N MOSFET (GGNMOS), where the source region and the first gate structure are electrically shorted and coupled to Vss, which is grounded, thereby grounding the source region and the first gate structure. The transistor also comprises a tap or body region that taps into the sub-fin, where the tap or body region is also referred to herein as a diffusion region. In an example, the diffusion region is in contact with the first portion of the sub-fin, and has the same doping type (e.g., p-type in case of an NMOS) as the first portion of the sub-fin. The body or tap region, e.g., the diffusion region, is also coupled to ground, in an example. The drain region is coupled to an I/O terminal, in some examples, although any node susceptible to ESD events can be so protected.

During a high voltage event (e.g., cause by an ESD event, for example) at an I/O terminal, the drain region that is coupled to the I/O terminal is also at the high voltage. However, the resistance imparted by the section 153 brings the voltage at or near the first gate structure to a relatively lower value (e.g., lower compared to the high voltage at the drain region). This prevents or reduces chances of breakdown of the gate dielectric material of the first gate structure. If the drain region was closer to the first gate structure (e.g., at a distance w1 from the first gate structure), the high voltage of the drain region would have imparted stress and increased possibility of a gate dielectric breakdown. However, because the drain region is at a relatively greater distance w2 from the gate electrode and because the section 153 acts as a resistor, the junction between the section 153 and the first gate structure experiences the relatively lower voltage, due to voltage drop within the section 153. This prevents or reduces chances of breakdown of the gate dielectric material of the first gate structure.

In the ESD protection transistor discussed herein above, the drain region extends vertically from the second portion of the sub-fin, like a pillar or a post. Also discussed herein is another ESD protection transistor comprising a drain region that has an “U” shape. For example, the U-shaped drain region comprises a first vertical end portion, a second vertical end portion, and an intermediate horizontal portion between the two end portions. Assume that the first end drain portion is nearer to the source region than the second end drain portion, where the second end drain portion is electrically coupled to the I/O terminal in this example case. For instance, the various portions of the drain region may be formed epitaxially during the same drain region formation process, and the various portions may in combination form the drain region. In an example, the first end drain portion may be adjacent to the first gate structure, such that first one or more nanoribbons now extend from the source region to the first end drain portion. Thus, the first end drain portion is adjacent to the first gate structure, and in contact with end portions of the first one or more nanoribbons. The two end drain portions are taller than the intermediate horizontal drain portion. In an example, the horizontal drain portion conjoins a lower section of the first end drain portion and a lower section of the second end drain portion. Also, a trench comprising dielectric material is laterally between an upper section of the first end drain portion and an upper section of the second end drain portion.

In an example, the second end drain portion is at a distance of w3 from the gate electrode of the first gate structure, and the source region is at the above discussed distance w1 from the gate electrode. In an example, distance w3 is greater than distance w1. The distance w3 may be similar to the distance w2 discussed herein above. Furthermore, similar to the above discussion, the diffusion (e.g., body or tap) region is electrically coupled to the ground terminal; and the source region and the gate electrode are electrically shorted and electrically coupled to the Vss, which is also electrically coupled to the ground. In an example, the second end drain portion is coupled to the I/O terminal.

In an example, the horizontal drain portion now acts as an extended drain in this ESD protection transistor. For example, the horizontal drain portion is conjoined with the second end drain portion, and is between the second end drain portion and the first gate structure. In operation, for example, during a high voltage event (e.g., cause by an ESD event, for example) at the I/O terminal, the second end drain portion (which is coupled to the I/O terminal) may be at a high voltage. However, the resistance imparted by the horizontal drain portion brings the voltage at or near the first gate structure to a relatively lower value (e.g., lower compared to the high voltage at the I/O terminal), e.g., due to the voltage drop within the horizontal drain portion. This prevents or reduces chances of breakdown of the gate dielectric material of the first gate structure.

The use of “group IV semiconductor material” (or “group IV material” or generally, “IV”) herein includes at least one group IV element (e.g., silicon, germanium, carbon, tin), such as silicon (Si), germanium (Ge), silicon-germanium (SiGe), and so forth. The use of “group III-V semiconductor material” (or “group III-V material” or generally, “III-V”) herein includes at least one group III element (e.g., aluminum, gallium, indium) and at least one group V element (e.g., nitrogen, phosphorus, arsenic, antimony, bismuth), such as gallium arsenide (GaAs), indium gallium arsenide (InGaAs), indium aluminum arsenide (InAlAs), gallium phosphide (GaP), gallium antimonide (GaSb), indium phosphide (InP), gallium nitride (GaN), and so forth. Note that group III may also be known as the boron group or IUPAC group 13, group IV may also be known as the carbon group or IUPAC group 14, and group V may also be known as the nitrogen family or IUPAC group 15, for example.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the material has an element that is not in the other material.

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For example, in some embodiments, such tools may be used to detect a transistor structure that includes (i) a sub-fin, (ii) a source region in contact with a first portion of the sub-fin, (iii) a drain region in contact with a second portion of the sub-fin, (iv) one or more bodies comprising semiconductor material above the sub-fin, the one or more bodies extending laterally between the source region and the drain region, (v) a gate structure on the one or more bodies, the gate structure comprising a gate electrode, and gate dielectric between the gate electrode and the one or more bodies, and (vi) a tap or body region (also referred to herein as a diffusion region) in contact with the first portion of the sub-fin, wherein a distance w2 between the drain region and the gate electrode is at least twice a distance w1 between the source region and the gate electrode, wherein the distances w1, w2 are measured in a same horizontal plane that runs in a direction parallel to the one or more bodies. In an example, the first portion of the sub-fin and the diffusion region are doped with a first type of dopant; and the second portion of the sub-fin, and the source and drain regions are doped with a second type of dopant different from the first type of dopant. In some further embodiments, such tools may also be used to detect the transistor structure in which the drain region has an “U” shape, such that the drain region includes a first vertical end portion, a second vertical end portion, and an intermediate horizontal portion between the two end portions, where the first vertical end portion is nearer to the source region than the second vertical end portion, and where the second vertical end portion is electrically coupled to an I/O terminal (or other terminal or node to be protected). Numerous configurations and variations will be apparent in light of this disclosure.

Architecture

FIGS. 1A-1D are cross-sectional views of an integrated circuit structure 100 (also referred to herein as a structure 100) that includes (i) a sub-fin 139, (ii) a source region 134 in contact with a first portion 142a of the sub-fin 139, (iii) a drain region 138a in contact with a second portion 140 of the sub-fin 139, (iv) one or more bodies 104d comprising semiconductor material above the sub-fin 139, the one or more bodies 104d extending laterally between the source region 134 and the drain region 138a, and (v) a gate structure 125d on the one or more bodies 104d, the gate structure 125d comprising a gate electrode 122d, and gate dielectric 123 between the gate electrode 122d and the one or more bodies 104d, wherein a distance w2 (see FIG. 1C for the distances) between the drain region 138a and the gate electrode 122d is at least twice a distance w1 between the source region 134 and the gate electrode 122d, wherein the distances w1, w2 are measured in a same horizontal plane that runs in a direction parallel to the one or more bodies 104d, in accordance with an embodiment of the present disclosure.

As can be seen, the cross-sectional view of FIG. 1A is taken parallel to, and through, the channel regions, such that the channel regions 104, and epitaxially formed source region 134 and drain regions 138a, 138b are shown. The cross-sectional view of FIG. 1B is along line A-A′ of FIG. 1A, and illustrates one stack of channel regions 104 and a gate electrode 122. For example, FIG. 1B illustrates a cross-sectional view of the channel regions 104. FIGS. 1C and 1D illustrate the structure 100 of FIG. 1A and further illustrate example connections for various regions of the structure 100, and are used to discuss functionality of the structure 100 of FIG. 1A.

In the example of FIG. 1A, one source region 134 and two drain regions 138a and 138b are illustrated, although the structure 100 can include any other appropriate number of such drain regions, such as one, three, or higher. The structure 100 includes a plurality of stack of channel regions 104, such as stacks of channel regions 104a, 104b, . . . , 104g, and a corresponding plurality of gate structures 125a, 125b, . . . , 125g, respectively.

In an example, individual channel regions 104 are wrapped around by a corresponding gate structure 125. In an example, the structure 100 is a GAA device in which each gate structure 125 wraps around corresponding individual channel regions 104. In an example, individual channel regions 104 are nanoribbons. As will be further appreciated in light of this disclosure, reference to nanoribbons is also intended to include other channel regions, such as nanowires or nanosheets, and other such semiconductor bodies around which a gate structure at least in part wraps. To this end, the use of a specific channel region configuration (e.g., GAA) is not intended to limit the present description to that specific channel configuration. In an example, the teachings of this disclosure may also be applicable to devices in which the gate at least partially wrap around the channel region, such as finFET structures having fins as channel regions. Thus, a stack of nanoribbon channel regions 104 may be replaced by a corresponding fin, in one example. Similarly, a stack of nanoribbon channel regions 104 may be replaced by a corresponding stack of nanowires or nanosheets, in another example.

In one embodiment, the structure 100 is formed on the sub-fin 139. In an example, the sub-fin comprises a plurality of portions 140, 142a, 142b. In an example where the transistor structure is a NMOS, the portions 142a and 142b comprise a p-type dopant, and the portion 140 comprises an n-type dopant. Example p-type dopants include boron, gallium, indium, and aluminum. Example n-type dopants include phosphorous and arsenic. However, in another example, the doping types are reversed for the portions (e.g., portions 142a and 142b comprising an n-type dopant, and portion 140 comprising a p-type dopant, for a PMOS device).

In an example, a doping concentration of the p-type dopant within the portion 142b is higher than a doping concentration of the p-type dopant within the portion 142a. Merely as an example, the doping concentration of the portion 142b is in the range of 1E14 to 1E24, and the doping concentration of the portion 142a is in the range of 1E12 to 1E20, although other suitable concentration ranges may also be possible. In an example, the portion 140 may have a doping concentration of the n-type dopant that is similar to the doping concentration of the p-type dopant within the portion 142a. Thus, in an example, the portion 142b is heavily doped p-type, the portion 142a is lightly doped p-type, and the portion 140 is lightly doped n-type (e.g., assuming an NMOS device). As also described herein below in further detail (e.g., with respect to the method 400), for example, deep implantation with higher energy maybe used for doping the portion 142b, and shallow implantation with lower energy maybe used for doping the portions 142a, 140.

In an example, the p-type portions 142a and 142b may merged to form a single p-type portion. Such a portion may have substantially uniform doping, or may have a graded doping concentration that decreases when traversing from bottom to the top of the portion.

As illustrated in FIG. 1A, in an example, the structure 100 comprises a plurality of stacks of nanoribbons 104, such as a stack of nanoribbons 104a, a stack of nanoribbons 104b, a stack of nanoribbons 104c, and so on. In the example of FIG. 1A, each vertical stack of nanoribbons 104 comprises three nanoribbons. The number of nanoribbons 104 in each vertical stack of nanoribbon (i.e., three nanoribbons per stack) is merely an example, and each vertical stack of nanoribbons may comprise a different number of nanoribbons, such as one, two, four, five or higher number of nanoribbons.

As illustrated, the vertical stack of nanoribbons 104d and the corresponding gate structure 125d are formed partly above the portion 142a of the sub-fin 139, and partly above the portion 140 of the sub-fin 139. For example, each of the nanoribbons 104d has (i) a first section adjacent to (and in contact with) the source region 134a, and (ii) a second section laterally adjacent to the first section and away from the source region 134, such that the first section is between the source region 134a and the second section. As illustrated in FIG. 1A, the first section of individual nanoribbons 104a is above the portion 142a, and the second section of individual nanoribbons 104a is above the portion 140. Similarly, a section of the gate structure 125d is above the portion 142a, and another section of the gate structure 125d is above the portion 140.

In an example, the structure 100 further comprises vertical stacks of nanoribbons 104a, 104b, and 104c that are above the portion 142a of the sub-fin 139. The structure 100 also comprises vertical stacks of nanoribbons 104e, 104f, 104g that are above the portion 140 of the sub-fin 139, as illustrated in FIG. 1A.

As illustrated, the vertical stack of nanoribbons 104d extends from the source region 134 towards the drain region 138a, and the vertical stack of nanoribbons 104e extends from the drain region 138a towards the source region 134. A trench 166a comprising dielectric material 165 separates the nanoribbons 104d and the nanoribbons 104e. For example, the dielectric material 166 is also on one or more components of the structure 100. The dielectric material 165 is laterally between, and in contact with, respectively end portions of the nanoribbons 104d and nanoribbons 104e.

The nanoribbons 104f extend from the drain region 138a to the drain region 138b. The nanoribbons 104g extend from the drain region 138b and away from the source region 134, as illustrated. An end section (e.g., the right end) of individual nanoribbons 104g may be in contact with the dielectric material 165 (or there may be further source or drains of other transistors on the right of the structure 100).

The nanoribbons 104a extend from a diffusion region 143 (discussed herein below) and away from the source region 134, as illustrated. An end section (e.g., the left end) of individual nanoribbons 104a is in contact with the dielectric material 165.

The nanoribbons 104b extend from the diffusion region 143 and toward the source region 134, as illustrated. An end section (e.g., the right end) of individual nanoribbons 104b is in contact with the dielectric material 165. Another trench 166b comprising the dielectric material 165 separates the nanoribbons 104b and the nanoribbons 104c. The dielectric material 165 is laterally between, and in contact with, respectively end portions of the nanoribbons 104b and nanoribbons 104c.

The nanoribbons 104 may comprise any appropriate semiconductor material, such as group IV material (e.g., silicon, germanium, or SiGe) or group III-V materials (e.g., indium gallium arsenide). In other embodiments, the nanoribbons 104 may be replaced by fins on which the corresponding gate structures are formed to provide double-gate or tri-gate configurations (as opposed to gate-all-around configurations with nanoribbons or wires). The nanoribbons 104 may be doped (e.g., same type of doping as the source and drain regions 134, 138a, 138b), partially doped (e.g., such as the example case where a nanoribbon is doped at its ends but not in the middle portion), or undoped, and may be shaped or sculpted during the gate formation process, according to some embodiments. In some cases, the nanoribbons 104 may be a multilayer structure, such as a SiGe body cladded with germanium, or a silicon body cladded with SiGe. Any number of channel configurations can be used.

According to some embodiments, the source and drain regions 134, 138a, 138b are epitaxial regions that are provided using an etch-and-replace process. In other embodiments one or more of the source and drain regions could be, for example, implantation-doped native portions of the semiconductor fins or substrate. Any semiconductor materials suitable for source and drain regions can be used (e.g., group IV and group III-V semiconductor materials). The source and drain regions may include multiple layers such as liners and capping layers to improve contact resistance. In any such cases, the composition and doping of the source and drain regions may be the same or different, depending on the polarity of the transistors. Any semiconductor materials suitable for source and drain regions can be used (e.g., group IV and group III-V semiconductor materials).

In the example of FIG. 1A, the structure 100 is of an NMOS transistor, in which the source and drain regions 134, 138a, and 138b are doped with n-type dopants. Note that in another example, the transistor can be a p-type transistor, in which the case the type of dopants of the source and drain regions (as well as the various portions of the sub-fin 139) would be reversed.

Also illustrated in FIG. 1A is a diffusion layer or region 143 in contact with the portion 142a of the sub-fin 139. In an example, the diffusion region 143 acts as a tap or body to the sub-fin 139, e.g., to tap the sub-fin 139 from outside the transistor. In an example, the diffusion region 143 is similar in structure to any of the source or drain regions 134, 138a, 138b. In an example, a doping concentration of the diffusion region 143 is similar to those of any of the source or drain regions 134, 138a, 138b. In an example, the diffusion region 143 is doped with p-type dopant for an NMOS device, and is doped with n-type dopant for a PMOS device. For example, the doping type of the diffusion region 143 is same as that of the portion 142a of the sub-fin 139, and opposite of that of the source and drain regions 134, 138a, 138b. In an example, the diffusion region 143 may be formed using processes that are similar to the processes of forming source or drain regions.

As illustrated, each source, drain, and diffusion regions 142, 134, 138a, 138b in part extend within the sub-fin 139. Extension of these regions within the sub-fin results in a better contact between the sub-fin and these regions, which facilitates in better current conduction through the transistor. For example, during formation of these regions, corresponding trenches are formed initially, and the source, drain, and diffusion regions are grown epitaxially within the trenches. The trenches for the source, drain, and diffusion regions are formed to extend within the sub-fin 139. In an example, the trenches 166a, 166b comprising the dielectric material 165 are also formed during the same processes as the trenches for the source, drain, and diffusion regions, although no source, drain, or diffusion regions are formed within the trenches 166a, 166b. Accordingly, in an example, the trenches 166a, 166b comprising the dielectric material 165 may also in part extend within the sub-fin 139, as illustrated in FIG. 1A.

In some embodiments, conductive contacts are formed over various regions of the structure 100. For example, conductive contacts 147a, 147b, 147c, 147d, and 147e are respectively formed on the diffusion region 143, source region 134, gate structure 125d, drain region 138a, and drain region 138b. The conductive contacts may be any suitably conductive material, such as one or more metals and/or alloys thereof. In some embodiments, conductive contacts include one or more of the same metal materials as gate electrode, or a different conductive material.

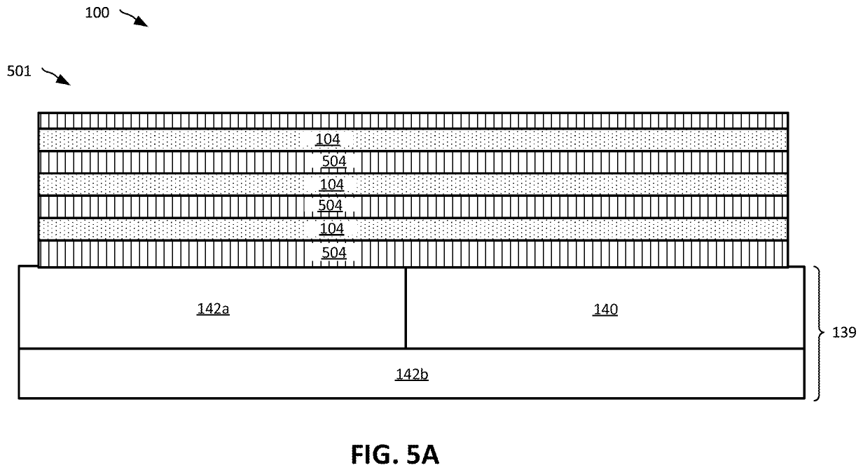

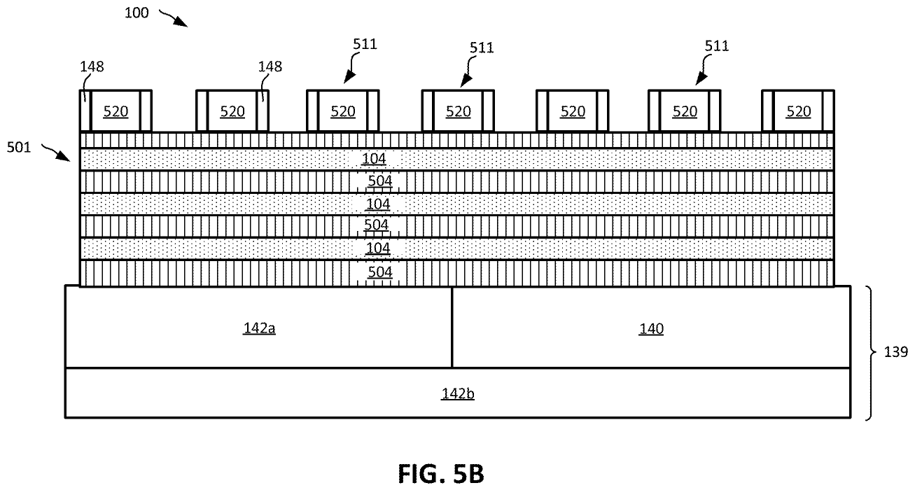

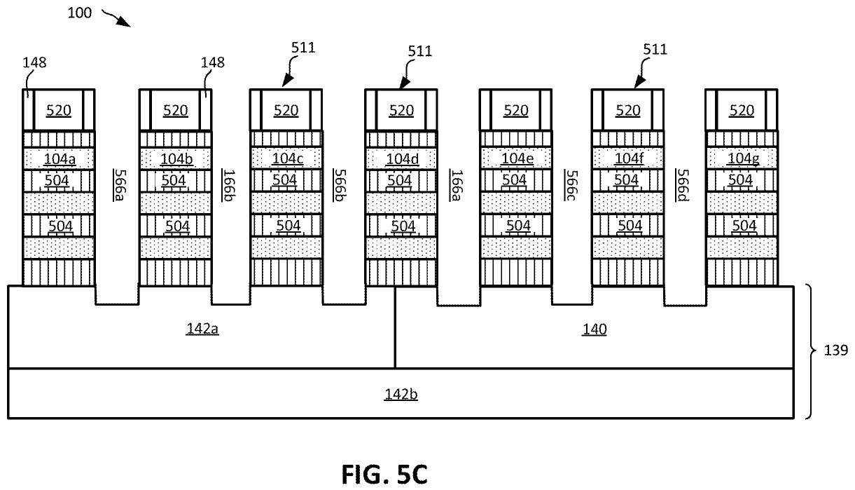

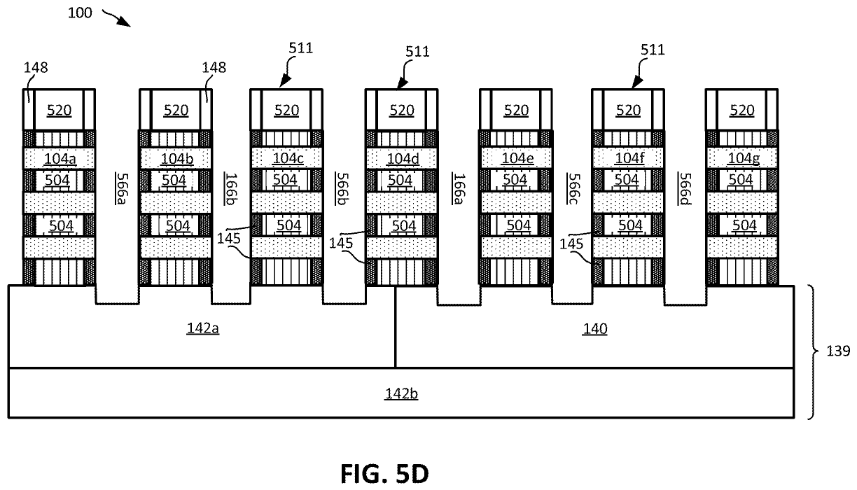

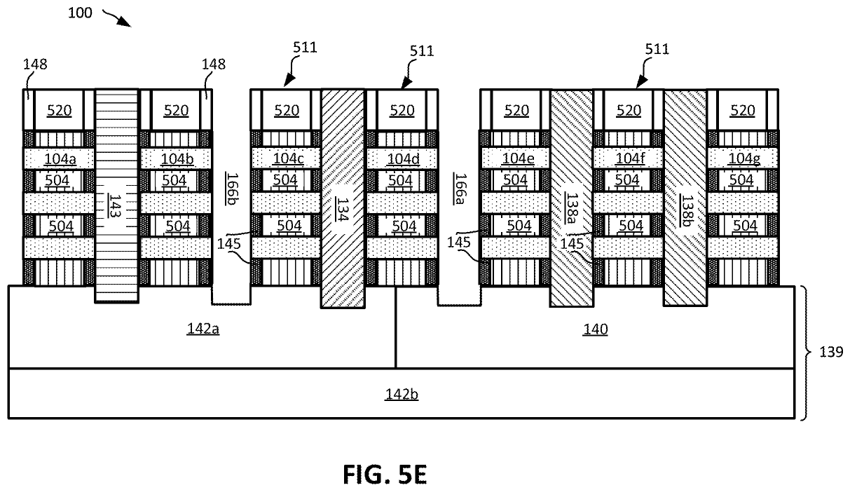

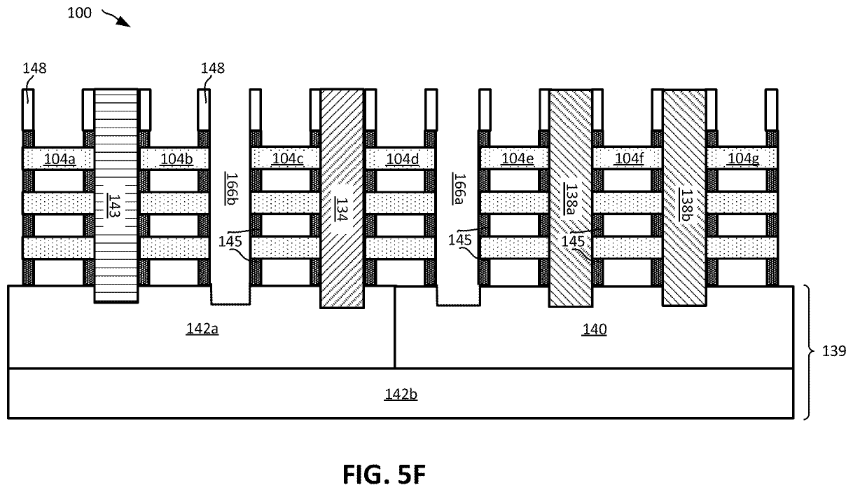

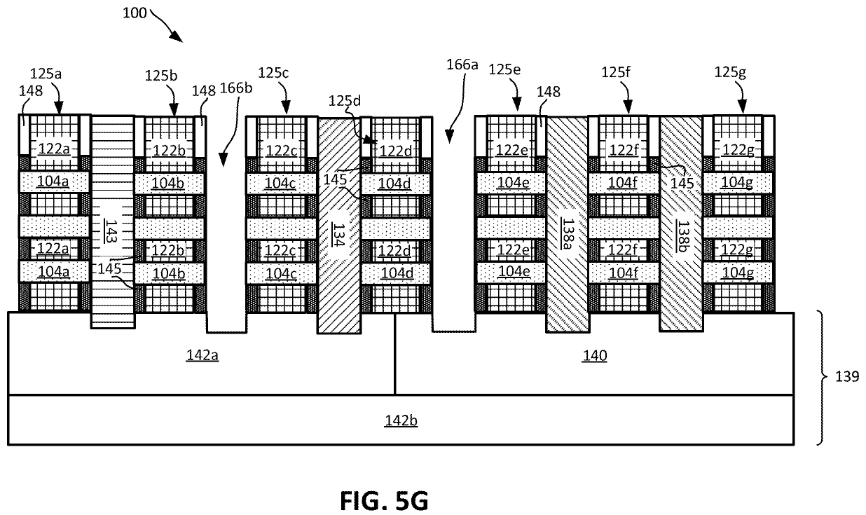

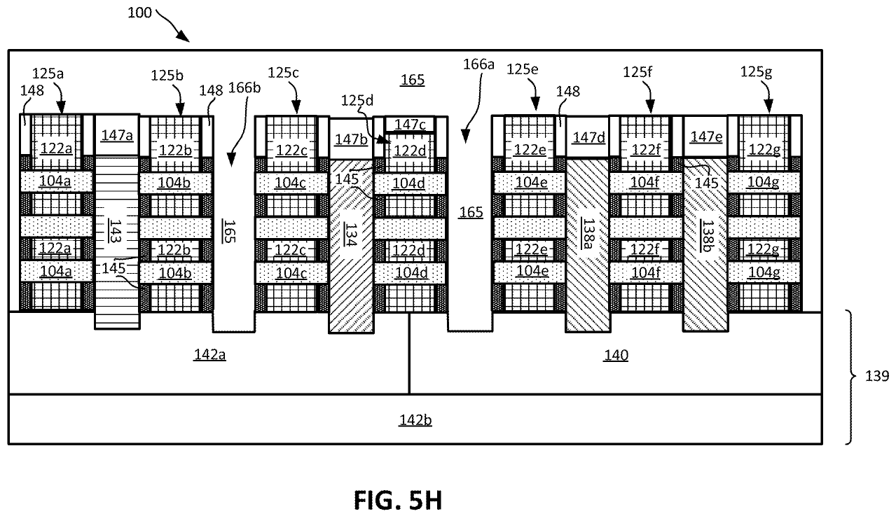

Note that in an example, the gate structures 125a, 125b, 125c, 125e, 125f, and/or 125g are not contacted. Thus, in an example, there are no corresponding gate contacts for these gate structures 125a, 125b, 125c, 125e, 125f, and/or 125g. In an example, the gate structures 125a, 125b, 125c, 125e, 125f, and/or 125g are inactive or dummy gate structures and are electrically floating, and do not impart any meaningful functionality in the structure 100. In an example, the gate structures 125a, 125b, 125c, 125e, 125f, and/or 125g are present in the structure 100, e.g., because gate structures are formed with regular pitch or interval within at least a section of a die that includes the structure, and the gate structures 125a, 125b, 125c, 125e, 125f, and/or 125g are formed as a part of a common or same gate structure formation processes. Note that the use of “inactive or dummy gate structure” is intended to imply that these gate structures do not have any meaningful functionality in the structure 100, and these inactive or dummy gate structures 125a, 125b, 125c, 125e, 125f, and/or 125g (comprising final metal gate electrodes 122) should not be confused with dummy gates (e.g., comprising polysilicon gate electrodes) that are sacrificial in nature, and temporarily formed during formation of the structure 100 (e.g., see dummy gates 511 of FIG. 5B).

A gate structure 125 contacts and wraps around corresponding individual nanoribbons 104. For example, the gate structure 125a contacts and wraps around individual nanoribbons 104a. As discussed herein above, in another example where the structure 100 includes a fin instead of a stack of nanoribbons, the corresponding gate structure in on and partly wraps around (e.g., is on three sides) of the fin.

In one embodiment, each gate structure 125 includes a gate dielectric 123 that wraps around middle portions of each nanoribbon, and a gate electrode 122 that wraps around the gate dielectric 123. The gate dielectric 123 is illustrated in an expanded view of a section 119 of the structure 100. For example, the gate electrode 122a of the gate structure 125a wraps around middle portions of individual nanoribbons 104a, the gate electrode 122b of the gate structure 125b wraps around middle portions of individual nanoribbons 104b, and so on. Note that the middle portion of each nanoribbon 104 is between a corresponding first end portion and a second end portion, where the first end portions of the nanoribbons of a stack is wrapped around by corresponding first inner gate spacer 145, and where the second end portions of the nanoribbons of a stack is wrapped around by corresponding second inner gate spacer 145.

In some embodiments, the gate dielectric 123 may include a single material layer or multiple stacked material layers. The gate dielectric 123 may include, for example, any suitable oxide (such as silicon dioxide), high-k dielectric material, and/or any other suitable material as will be apparent in light of this disclosure. Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. The high-k dielectric material (e.g., hafnium oxide) may be doped with an element to affect the threshold voltage of the given semiconductor device. According to some embodiments, the doping element used in gate dielectric 123 is lanthanum. In some embodiments, the gate dielectric can be annealed to improve its quality when high-k dielectric material is used. In some embodiments, the gate dielectric 123 includes a first layer (e.g., native oxide of nanoribbons, such as silicon dioxide or germanium oxide or SiGe-oxide) on the nanoribbons, and a second layer of high-k dielectric (e.g., hafnium oxide) on the first layer. The gate dielectric 123 is present around middle portions of each nanoribbon, and although not illustrated, may also be present over sub-fin portions 142a, 140, and/or on inner sidewalls of the inner gate spacers 145.

In one embodiment, one or more work function materials (not illustrated in FIG. 1A) may be included around the nanoribbons 104. Note that work function materials are called out separately, but may be considered to be part of the gate electrodes. In this manner, a gate electrode 122 may include multiple layers or components, including one or more work function materials, gate fill material, capping or resistance-reducing material, to name a few examples. In some embodiments, a p-channel device may include a work function metal having titanium, and an n-channel device may include a work function metal having tungsten or aluminum, although other material and combination may also be possible. In some other embodiments, the work function metal may be absent around one or more nanoribbons. In still other embodiments, there may be insufficient room for any gate fill material, after deposition of work function material (i.e., a given gate electrode may be all work function material and no fill material). In an example, the gate electrodes 122 may include any sufficiently conductive material, such as a metal, metal alloy, or doped polysilicon. The gate electrodes may include a wide range of materials, such as polysilicon or various suitable metals or metal alloys, such as aluminum, tungsten, titanium, tantalum, copper, cobalt, molybdenum, titanium nitride, or tantalum nitride, for example. Numerous gate structure configurations can be used along with the techniques provided herein, and the present disclosure is not intended to be limited to any particular such configurations.

Each gate structure 125 also includes two corresponding inner gate spacers 145 that extend along the sides of the gate electrode 122, to isolate the gate electrode 122 from an adjacent source or drain region (or from the trenches 166a or 166b). The inner gate spacers 145 at least partially surround the end portions of individual nanoribbons. In one embodiment, inner gate spacers 145 may include a dielectric material, such as silicon nitride, for example. An upper portion of each gate electrode 122 has gate spacers 148 on its side surfaces, to separate the gate electrode 122 from adjacent source or diffusion or drain region (or source or drain or diffusion contact).

As discussed herein above, the gate structures 125a, 125b, 125c, 125e, 125f, and/or 125g are inactive or dummy gates structures, e.g., are electrically floating, whereas the gate structure 125d is coupled to an external circuit through the gate contact 147d. As the gate structures 125a, 125b, 125c, 125e, 125f, and/or 125g are inactive or dummy gates, the gate structures 125a, 125b, 125c, 125e, 125f, and/or 125g do not impart any meaningful control over the corresponding nanoribbons 104a, 104b, 104c, 104e, 104f, and/or 104g, respectively.

Note that one end of each of the nanoribbons 104a, 104b, 104c, 104d, 104e, 104g (e.g., except nanoribbon 104f) is in contact with a source, drain, or diffusion region 134, 138a, 138b, 143, while the other end of each of these nanoribbons 104a are not coupled to any source or drain or diffusion region. Accordingly, these nanoribbons 104a, 104b, 104c, 104d, 104e, 104g do not conduct any current.

Furthermore, the nanoribbons 104f are coupled between two drain regions 138a and 138b. In an example, the drain region 138b may be shorted to the drain region 138a though the respective contacts 147d and 147e. In another example, the drain region 138b may be electrically floating, e.g., not coupled to an external circuit, and the drain contact 147e may be absent. In yet another example, the drain region 138b may be absent from the structure 100. Accordingly, in some examples, the nanoribbons 104f also may not conduct any current.

Thus, the nanoribbons 104 of the structure 100 may not conduct any current, and may not impart any meaningful functionality in the structure 100. In an example, the structure 100 is formed laterally adjacent to one or more other transistor structures, such as one or more other GAA transistor structures comprising GAA channel regions (such as nanoribbons). Common or same channel region formation processes are performed across multiple such transistor structures in at least a section of the die. Because of the same channel region formation processes, the nanoribbon channel regions 104 are also formed within the device 100, e.g., even though the nanoribbons may not conduct any current.

Note that as previously discussed herein, both the drain region 138a and the portion 140 of the sub-fin 139 are doped using a same type of dopant, e.g., an n-type dopant, e.g., in case the structure 100 is an NMOS (the dopant types are reversed, if the structure 100 is a PMOS, as will be appreciated). Referring to FIG. 1C, a section 153 of the portion 140 of the sub-fin 139, which is between (i) the drain region 138a and (ii) the junction between the portions 140, 142a, may be considered as an extension of the drain region 138a. Note that the boundary of the section 153 is approximately illustrated in FIG. 1C. For example, as both the epitaxially formed drain region 138a and the section 153 of the portion 140 of the sub-fin 139 are doped with same type of dopant, the section 153 forms an extension of the drain region 138a. Thus, the section 153, from a functional perspective of the structure 100, can be considered to be same as the drain region 138a.

As illustrated in FIG. 1B, each gate electrode 122 in part wraps around a corresponding section of the sub-fin 139. For example, the gate electrode 122d is on three sides of a section of the sub-fin 139, as illustrated in FIG. 1B. Note that such partial wrapping of the sub-fin is not visible in the cross-section of FIG. 1A. However, FIG. 1B illustrates the gate electrode 122d being on three sides of the sub-fin 139 (e.g., similar to a tr-gate or fin-based structure), and other gate electrodes would also similarly be on three sides of corresponding sections of the sub-fin 139. For example, in FIG. 1A, the gate electrode 122d would be on top, and in front and back of the sub-fin 139, although the gate electrode 122d being in front and back of the sub-fin 139 is not visible in the cross-section of FIG. 1A. Thus, the gate electrode 122d (and various other gate electrodes) can exert meaningful control on flow of current through a corresponding portion of the sub-fin 139, e.g., an area of the sub-fin 139 below the nanoribbons 104d.

For example, referring to FIG. 1C, the gate structure 125d including the gate electrode 122d can be on three sides of at least a part of the section 152 of the portion 142a of the sub-fin 139. Accordingly, in an example, the section 152 below the gate structure 125d acts as a channel region for the transistor structure 100. Current conduction through the section 152 may be based on voltages on the source region 134, drain region 138a, and the gate structure 125d. For example, current conduction through the section 152 may be controlled by controlling the gate voltage of the gate electrode 125d. In an example, the resultant NMOS transistor characteristics can be tuned by controlling the lateral length of the section 152 and/or doping level of the section 152.

As illustrated in FIG. 1C, the source region 134 is at a lateral distance w1 from the gate electrode 122d, and the drain region 138a is at a distance w2 from the gate electrode 122d. In one embodiment, the distance w2 is greater than the distance w1. For example, w1 is equal to a width of the inner gate spacer 145. Also, w2 is a sum of (i) a width of an inner gate spacer 145, (ii) a width of the trench 166a (which is equal to a width of a source or drain region), (iii) a width of another inner gate spacer 145, (iv) a width of the gate electrode 122e, and (v) a width of yet another inner gate spacer 145. In an example, distance w2 is at least 2×, or at least 3×, or at least 4×, or at least 5×, or at least 6×, or at least 10, or at least 12×, or at least 20× the distance w1, and “×” denotes times or multiplication (e.g., “2×” implies that w2 is twice w1). In an example, distance w2 is at least 1 nm, or at least 2 nm, or at least 4 nm, or at least 6 nm, or at least 8 nm, or at least 10 nm, or at least 12 nm, or at least 14 nm, or at least 16 nm, or at least 20 nm more than the distance w1.

Thus, the width w2 is relatively high (e.g., substantially greater than the width w1), and the drain region 138a is effectively extended within the section 153 of the portion 140 of the sub-fin 139. Accordingly, effectively or functionally, this is akin to adding a series resistance with the drain region 138a, where a value of such a resistance is based on a lateral length of the section 153, a doping level of the portion 140, and/or a depth of the undercut of the trench 166a (e.g., an extent to which the trench 166a extends within the sub-fin 139, which can be controlled during formation or patterning of the trench 166a). For example, the section 153 adds a resistance between the drain region 138a and the section 152, where the section 152 forms a channel region of the transistor structure, as discussed herein above.

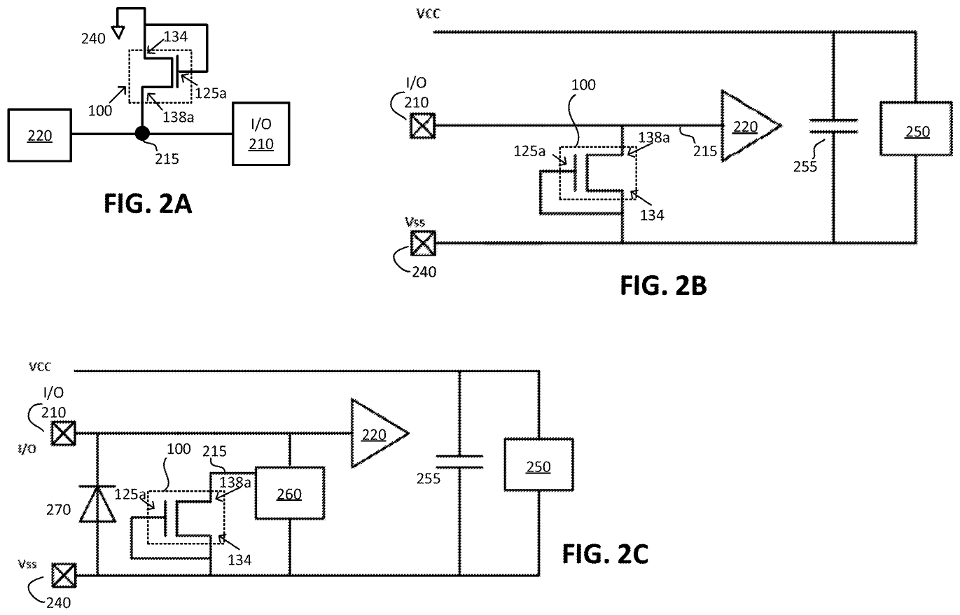

For example, during a high voltage event (e.g., cause by an ESD event, for example) at an I/O terminal 210 (see FIGS. 2A-2C below), the drain region 138a that is coupled to the I/O terminal 210 is also at the high voltage. However, the resistance imparted by the section 153 brings the voltage at or near the gate structure 125d to a relatively lower value (e.g., lower compared to the high voltage at the drain region 138a). This prevents or reduces chances of breakdown of the gate dielectric material 123 of the gate structure 125d. If the drain region 138a was closer to the gate structure 125d (e.g., at a distance w1 from the gate structure 125a), the high voltage of the drain region 138a would have imparted stress and increased possibility of a gate dielectric breakdown. However, because the drain region 138a is at a relatively greater distance w2 from the gate electrode 125a and because the section 153 acts as a resistor, the junction between the section 153 and the gate structure 125d experiences the relatively lower voltage, due to voltage drop within the section 153. This prevents or reduces chances of breakdown of the gate dielectric material 123 of the gate structure 125d.

FIG. 1C also symbolically illustrates (e.g., using dashed lines) various connections of the structure 100, for some example applications of the structure 100. For example, the structure 100 may be configured as a ground-gate N MOSFET (GGNMOS), where the source region 134 and the gate structure 125d are electrically shorted and coupled to a Vss 240, e.g., using one or more interconnect features 192. In an example, the Vss 240 is grounded, thereby grounding the source region 134 and the gate structure 122d. Similarly, the body or tap region 143, e.g., the diffusion region 143, is also coupled to ground 245, in an example, using one or more interconnect features 196. The drain region 138a is coupled to an I/O terminal 210 (see FIGS. 2A-2C discussed herein below), using one or more interconnect features 194.

Note that interconnect features 192, 194, 196 are symbolically illustrated, without illustrating actual structure of these interconnect features. The interconnect features 192, 194, 196 comprise conductive vias and conductive lines, and may include one or more metallization levels of the die.

FIGS. 2A-2C illustrate example applications of the structure 100 of FIGS. 1A-1D, in accordance with an embodiment of the present disclosure. Each of FIGS. 2A-2C provides a schematic of the transistor structure 100 discussed with respect to FIGS. 1A-1D, configured for ESD protection of a circuit 220 coupled to an I/O terminal 210. The circuit 220 may include any core circuitry (e.g., CMOS circuitry), such as but not limited to, microprocessor logic gates, memory cells, or another appropriate circuit of a die. As shown in FIG. 2A, the circuit 220 is electrically connected to an I/O 210, through which the circuit 220 may interface with devices external to the IC chip on which the circuit 220 is implemented. The I/O terminal 210 may be any I/O pad, pin, post, wire, etc. Further note that terminal 210 can be any terminal or node to be protected from ESD events, and need not be limited to an I/O terminal. The transistor structure 100 may serve as an ESD protection device by being electrically connected to a circuit node 215 disposed between the circuit 220 and the I/O 210. In the examples illustrated in FIGS. 2A-2C, the transistor structure 100 is in a GGNMOS configuration. In this configuration, in normal operating mode, the ESD protection device that is the transistor structure 100 remains in an “off-state” with the channel region (e.g., section 152, see FIG. 1C) of the transistor structure 100 conducting very little leakage current because of the grounded gate electrode 125a being present. As shown in each of FIGS. 2A-2C, the source region 134 of the transistor structure 100 may be electrically connected to the gate of the transistor structure 100, and both may be connected to a ground potential 240, e.g., Vss, while a drain region 138a of the transistor structure 100 may be electrically coupled to the circuit node 215 disposed between the circuit 202 and the I/O 210.

FIGS. 2A and 2B illustrate embodiments where the circuit 220 may be a receiver, e.g., a radio frequency (RF) receiver. In the example of FIG. 2B, the transistor structure 100 may considered to be a stand-alone GGNMOS, used with gate and source connected to ground node and drain connected to the exposed I/O terminal 210. In the example of FIG. 2C, the transistor structure 100 is a GGNMOS that may also be used as a trigger for a Silicon Controlled Rectifier (SCR) 260 which may be used for ESD protection, where, in some embodiments, a combination of the transistor structure 100 and the SCR 260 may be used in conjunction with a diode 270 for ESD protection. As shown in FIG. 2C, one port of the SCR 260 may be coupled to the drain region 138a of the transistor structure 100, another port of the SCR 260 may be coupled to each of the circuit 220 and the I/O terminal 210, while the third port of the SCR 260 may be coupled to the ground node/potential 240. As also shown in FIG. 2C, the diode 270 may be coupled between the I/O terminal 210 and the ground terminal 240.

Each of FIGS. 2B and 2C further illustrate an optional rail clamp 250, which may be configured to sink current to ground in the event of an ESD spike. Each of FIGS. 2B and 2C further illustrate an optional capacitor 255, which may be configured to sink current to ground in the event of an ESD spike.

FIG. 1D illustrate an NPN bipolar junction (BJT) transistor 180 effectively formed within the structure 100 of FIG. 1A. For example, referring to FIGS. 1C and 1D, the n-type doped drain region 138a and the section 153 (see FIG. 1C) form the first n-type region of the transistor 180. Note that the section 153 contributes to formation of the resistor 184 in series with the n-type drain region 138a. The n-type doped source region 134 forms the second n-type region of the transistor 180. Sandwiched between the two n-type regions is the p-type section 152 (see FIG. 1C) of the portion 142a of the sub-fin 139. The region 143 acts as a gate of the transistor 180. Note that the region 143, source region 134, and gate structure 125 are coupled and grounded, as discussed with respect to FIGS. 1C and 2A-2C. During a high voltage and/or current event at the drain region 138a (due to an ESD event, for example), the transistor 180 enters in a snapback mode, and the transistor begins to shunt the ESD current to ground, protecting the core circuit 220 (see FIGS. 2A-2C) from the ESD stress.

Thus, as discussed herein above, the resistor 184 formed by the section 153 reduces a high ESD voltage at the drain region 138a to a lower voltage between a junction of section 153 and the gate structure 125d. As also discussed herein above, this prevents or reduces chances of breakdown of the gate dielectric material 123 of the gate structure 125d, e.g., during an ESD event.

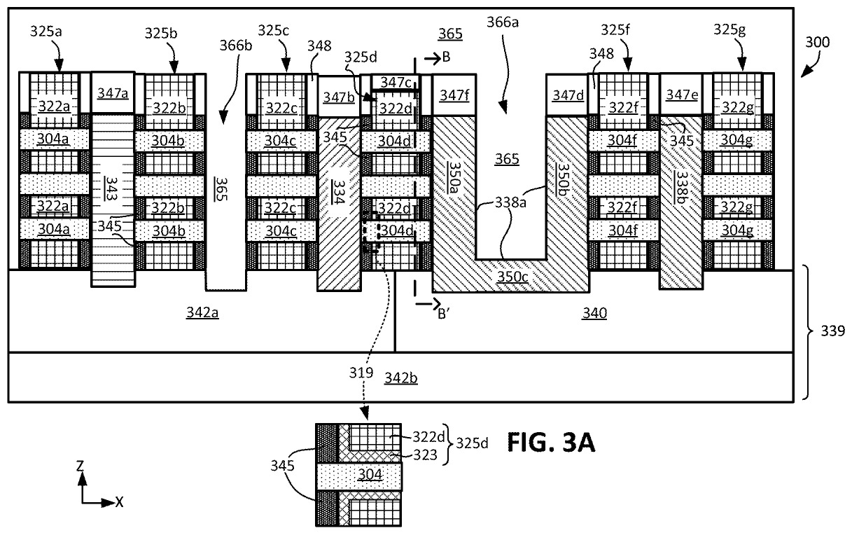

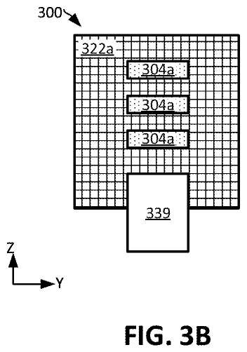

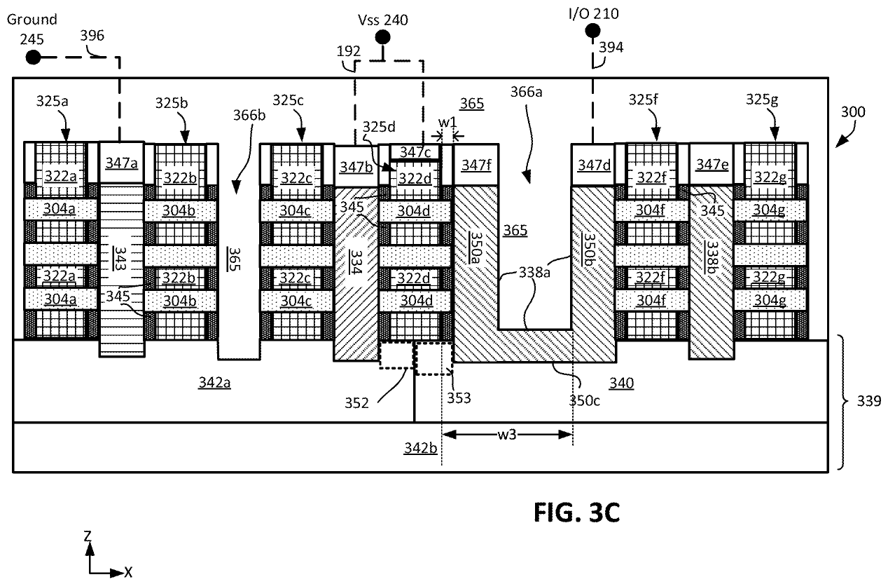

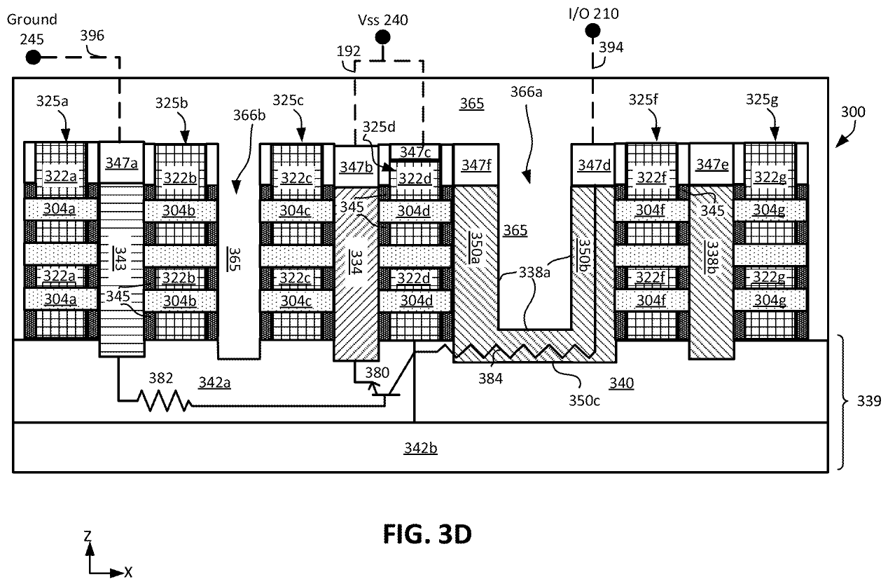

FIGS. 3A-3D are cross-sectional views of an integrated circuit structure 300 (also referred to herein as a structure 300) that includes (i) a sub-fin 339, (ii) a source region 334 in contact with a first portion 342a of the sub-fin 339, (iii) a drain region 338a in contact with a second portion 340 of the sub-fin 339, wherein the drain region 338a comprises a first vertical end portion 350a, a second vertical end portion 350b, and an intermediate horizontal portion 350c between the two end portions 350a, 350b, wherein the first vertical end portion 350a is nearer to the source region 334 than the second vertical end portion 350b, and wherein the second vertical end portion 350b is electrically coupled to an I/O terminal 210, in accordance with an embodiment of the present disclosure.

As can be seen, the cross-sectional view of FIG. 3A is taken parallel to, and through, the channel regions, such that the channel regions 304, and epitaxially formed source and drain regions 334, 338a, 338b are shown. The cross-sectional view of FIG. 3B is along line B-B′ of FIG. 3A, and illustrates one stack of channel regions 304 and a gate electrode 322. For example, FIG. 3B illustrates a cross-sectional view of the channel regions 304. FIGS. 3C-3D illustrate cross-sectional view of the structure 300 of FIG. 3A, and are used to discuss functionality of the structure 300.

Various components of the structure 300 are at least in part similar to the corresponding components of the structure 100. For example, similar to the diffusion region 143, the source region 134, and the drain region 138b of the structure 100, the structure 300 comprises a diffusion region 343, the source region 334, and the drain region 338b. Also, the gate structures 325a, 325b, 325c, 325d, 325f, and 325g (e.g., including corresponding gate electrodes 322, gate dielectric 323, and inner gate spacers 345) are similar to the corresponding gate structures within the structure 100. Furthermore, the structure 300 includes stacks of nanoribbons 104, which are similar to the stacks of nanoribbons 104 of the structure 100. Portions 340, 342a, 342b of sub-fin 339 of the structure 300 are similar to corresponding portions of the sub-fin 139 of the structure 100. Discussion of the same components with respect to the structure 100 also applies to the corresponding components of the structure 300.

The structure 100 of FIGS. 1A-1D includes a drain region 138a. In contrast, the structure 300 of FIGS. 3A-3D includes a drain region 338a that has a shape different from the drain region 138a. For example, the drain region 338a includes the vertical end portions 350a and 350b, and an intermediate horizontal portion 350c between the two end portions 350a, 350b. For example, the portions 350a, 350b, 350c may be formed epitaxially during the same drain region formation process, and the portions 350a, 350b, 350c may in combination form the drain region 338a. In an example, there may not be any seam or interface between the portions 350a, 350b, 350c. As illustrated, the portion 350a is adjacent to the gate structure 325d, and in contact with end portions of the nanoribbons 304d. The portion 350b is adjacent to the gate structure 325f, and in contact with end portions of the nanoribbons 304f The portion 350c is on the portion 340 of the sub-fin 339. The end portions 350a, 350b are taller than the portion 350c of the drain region 338a, as illustrated in FIG. 3A. In an example, the horizontal portion 350c conjoins a lower section of the vertical portion 350a and a lower section of the vertical portion 350b. Also, a trench 366a comprising dielectric material 365 is laterally between an upper section of the vertical portion 350a and an upper section of the vertical portion 350b. Thus, the trench 366a extends within the drain region 338a, and is surrounded on three sides by the drain region 338a.

As illustrated in FIG. 3C, the portion 350b is at a distance of w3 from the gate electrode 322d, and the source region 334 is at a distance of w1 from the gate electrode 322d. In an example, distance w3 is greater than distance w1. The distance w3 may be similar to the distance w2 of the structure 100, and comparison between distances w3 and w1 may be similar to the above discussed comparison between the distances w2 and w1.

As illustrated, similar to the connection of the structure 100 (see FIG. 1C), in the structure 300 (see FIG. 3C), the diffusion region 343 is electrically coupled to the ground terminal 245 through one or more interconnect features 396, and the source region 334 and the gate electrode 322d are electrically shorted and electrically coupled to the Vss 240, which is also electrically coupled to the ground.

The drain region 338a is coupled to the I/O terminal 210. Specifically, the end portion 350b of the drain region 338a is coupled to the I/O terminal 210. The I/O terminal 210 and the ground terminal 245 have been discussed herein above with respect to the structure 100.

In an example, the doping types of various components of the structure 300 are similar to the corresponding components of the structure 100. For example, in the structure 300, assuming an NMOS device, the portions 342a, 342b, and diffusion region 343 are all doped with p-type dopant, and the portion 340 and the source and drain regions 334, 338a, 338b are doped with n-type dopant. The doping types may be reversed for a PMOS configuration.

Referring now to FIG. 3C, illustrated is a section 352 within the portion 342a of the sub-fin 339 and under the gate structure 325d. As discussed with respect to FIG. 1C and as also illustrated in FIG. 3B, the section 352 has the gate structure 325d on three sides (e.g., on top, front, and back, like a tri-gate structure). Accordingly, for reasons discussed in further detail with respect to FIG. 1C, in an example, the section 352 of the portion 342a of the sub-fin 339 forms an active channel region of the transistor structure 300.

Furthermore, the nanoribbon 104d of the structure 100 of FIGS. 1A-1D did not extend from a source region to a drain region. In contrast, the nanoribbons 304d of the structure 300 of FIGS. 3A-3D extend from the source region 334 to the portion end 350a of the drain region 338a. Accordingly, the nanoribbons 304d may also conduct current, and form active channel region between the source region 334 and the portion end 350a of the drain region 338a. However, in an example, the section 352 (see FIG. 3C) of the sub-fin 339 offers a lower resistance path between the source region 334 and the drain region 338a, e.g., compared to the resistance of the path through the nanoribbons 304d. Accordingly, the section 352 would conduct a majority of current between the portion 350b of the drain region 338a and the source region 334, although the nanoribbons 304d may conduct some current. For example, referring to both FIGS. 3C and 3D, the current may flow between the terminals Vss 240 and I/O 210, through (i) the contact 347d, (ii) the portion 350b of the drain region 338a, (iii) the portion 350c of the drain region 338a, (iv) the sections 353 and 352 and/or though the nanoribbons 304d, (v) the source region 334, and (vi) the contact 347b.

In an example, during a high voltage event (e.g., cause by an ESD event, for example) at the I/O terminal 210, the portion 350b of the drain region 338a (which is coupled to the I/O terminal 210) may be at a high voltage. However, as illustrated in FIG. 3D, the resistance 384 imparted by the portion 350c of the drain region 338a brings the voltage at or near the gate structure 325d to a relatively lower value (e.g., lower compared to the high voltage at the portion 305a of the drain region 138a), e.g., due to the voltage drop within the portion 350c. This prevents or reduces chances of breakdown of the gate dielectric material 323 of the gate structure 325d. If the portion 350b of the drain region 338a was closer to the gate structure 325d (e.g., if the horizontal portion 350c of the drain region 338a was absent), the high voltage of the portion 350b of the drain region 338a would have imparted stress and increase possibility of a gate dielectric breakdown. However, because the portion 350b of the drain region 338a is at a relatively greater distance w3 from the gate electrode 125a, the junction between the section 353 and the gate structure 325d experiences the relatively lower voltage, to prevent or reduce chances of breakdown of the gate dielectric material 323 of the gate structure 325d.

In an example, the structure 300 may be used similarly to the structure 100. For example, discussion regarding applications of the structure 100, as discussed with respect to FIGS. 2A-2C, also applies to the structure 300 of FIGS. 3A-3D.

FIG. 3D illustrate an NPN bipolar junction (BJT) transistor 380 effectively formed within the structure 300 of FIGS. 3A-3D. For example, referring to FIGS. 3C and 3D, the n-type doped portions 350b, 350c, and the section 353 (see FIG. 3C) form the first n-type region of the transistor 380. Note that the section 352 and the portion 350c of the drain region 338a contribute to formation of the resistor 384 of FIG. 3D. The n-type doped source region 334 forms the second n-type region of the transistor 380. Sandwiched between the two n-type regions is the p-type section 352 (see FIG. 3C) of the portion 342a of the sub-fin 339. The diffusion region 343 acts as a gate of the transistor 380. Note that the diffusion region 343, source region 334, and gate structure 325 are shorted to the grounded, as discussed with respect to FIGS. 3C and 2A-2C. During a high voltage and/or high current event at the portion 350b of the drain region 338a (due to an ESD event at the I/O terminal 210, for example), the transistor 380 enters in a snapback mode, and the transistor begins to shunt the ESD current to ground, protecting the core circuit 220 (see FIGS. 2A-2C) from the ESD stress.

Note that as discussed herein above, the resistor 384 formed by the portion 350c of the drain region 338a and the section 153 reduces a high ESD voltage at the portion 350b of the drain region 338a to a lower voltage between a junction of section 353 and the gate structure 325d. As also discussed herein above, this prevents or reduces chances of breakdown of the gate dielectric material 323 of the gate structure 325d, e.g., during an ESD event.

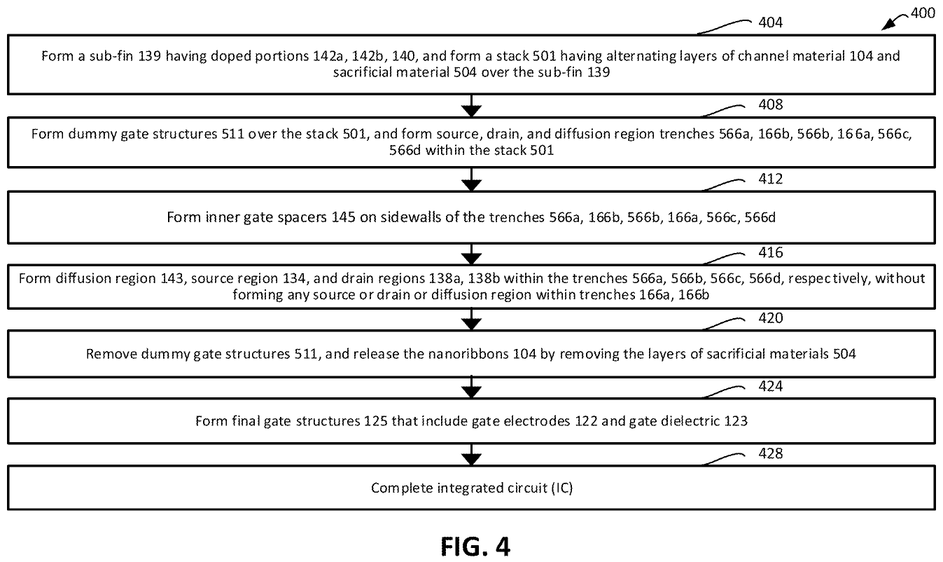

FIG. 4 illustrates a flowchart depicting a method 400 of forming an integrated circuit structure (such as the integrated circuit structure 100 of FIGS. 1A-1D), in accordance with an embodiment of the present disclosure. FIGS. 5A, 5B, 5C, 5D, 5E, 5F, 5G, and 511 collectively illustrate cross-sectional views of the integrated circuit structure in various stages of processing in the methodology of FIG. 4, in accordance with an embodiment of the present disclosure. FIGS. 4 and 5A-5G will be discussed in unison.

Referring to FIG. 4, the method 400 includes, at 404, from frontside of the integrated circuit structure 100, forming a sub-fin 139 having appropriately doped portions 142a, 142b, 140, and forming a stack 501 having alternating layers of channel material 104 and sacrificial material 504 over the sub-fin 139, as illustrated in FIG. 5A. The various portions of the sub-fin 139 may be appropriately doped using appropriate implantation techniques. For example, deep implantation with higher energy maybe used for doping the portion 142b, and shallow implantation with lower energy maybe used for doping the portions 142a, 140. The various layers within the stack 501 may be formed using an appropriate deposition process, such as chemical vapor deposition (CVD), physical vapor deposition (PVD), atomic layer deposition (ALD), vapor-phase epitaxy (VPE), molecular beam epitaxy (MBE), or liquid-phase epitaxy (LPE), for example. In an example, the sacrificial material 504 may comprise a semiconductor material, such as SiGe, that is etch selective with respect to the channel material 504 (e.g., Si, or other appropriate semiconductor material, discussed above). For example, an etch process to remove the sacrificial material 508 may not substantially etch the channel material 504.

Referring again to FIG. 4, the method 400 then proceeds from 404 to 408, which includes forming dummy gate structures 511 over the stack 501, and forming trenches 566a, 166b, 566b, 166a, 566c, 566d within portions of the stack 501 not covered by the dummy gate structures 511, as illustrated in FIGS. 5B and 5C. In an example, each dummy gate structure 511 comprises dummy gate oxide (not labelled in FIG. 5B), dummy gate electrode 520 (e.g., comprising polysilicon, for example), and gate spaces 148. In one embodiment, forming the dummy gate structure 511 may include deposition of a dummy gate oxide, and deposition of a dummy gate electrode 520 (e.g., poly-Si). Gate spacers 148 are formed along opposite sides of the dummy gate electrode 511. For example, the gate spacers 148 comprise silicon nitride (Si₃N₄) and/or other suitable dielectric material, as will be appreciated. The dummy gates are formed in positions where the final metal gates are to be eventually formed for the structure 100.

Formation of the various trenches 566 and 166 may be performed using an appropriate etch process. Note that the diffusion region, and the source and drain regions will make electrical contact with the sub-fin. Accordingly, in an example, the trenches extend at least in part within the sub-fin, e.g., such that the later formed regions will have a better electrical contact with the sub-fin. Also, the various trenches divide the stack 501 of channel material 104 into multiple stacks comprising nanoribbons 104a, 104b, . . . , 104g of the structure 100, interleaved with the sacrificial material 504, see FIG. 5C.

Referring again to FIG. 4, the method 400 then proceeds from 408 to 412, where inner gate spacers 145 are formed on sidewalls of the trenches 566a, 166b, 566b, 166a, 566c, 566d, as illustrated in FIG. 5D. The inner gate spacers 145 may be formed using processes used to form such inner gate spacers in GAA transistors. For example, end portions of the sacrificial materials 504 of FIG. 5C are etched (e.g., using a wet etch that uses nitric acid/hydrofluoric acid, an anisotropic dry etch, or other suitable etch process) through the trenches 566a, 166b, 566b, 166a, 566c, 566d, to form corresponding recesses, and the inner gate spacers 145 are deposited using an appropriate deposition technique (e.g., CVD, PVD, ALD, VPE, MBE, or LPE, for example) within the thus formed recesses. The deposited inner gate spacers 145 may be planarized, such that tips of the channel materials 104 are exposed through the trenches 566a, 166b, 566b, 166a, 566c, 566d.

Referring again to FIG. 4, the method 400 then proceeds from 412 to 416, where diffusion region 143, source region 134, and drain regions 138a, 138b are formed (e.g., grown epitaxially) within the trenches 566a, 566b, 566c, 566d, respectively, without forming any source or drain or diffusion region within trenches 166a, 166b, as illustrated in FIG. 5E. In an example, the regions 143, 134, 138a, 138b are formed epitaxially within the corresponding trenches. In some embodiments, these regions may include any suitable doping scheme, such as including suitable n-type and/or p-type dopant (e.g., in a concentration in the range of 1E16 to 1E22 atoms per cubic cm), as discussed above. Dopant types of various diffusion regions have been discussed herein above.

Note that each of the source and drain regions 134, 138a, 138b has a first type of dopant (e.g., n-type for NMOS), whereas the diffusion region 143 has a second type of dopant (e.g., p-type for NMOS). In an example, when forming regions having p-type dopant, trenches for regions having n-type dopant are being masked off; and similarly, when forming regions having n-type dopant, trenches for regions having p-type dopant are being masked off, e.g., such that individual regions may be appropriately doped with either p or n type dopant. Accordingly, in an example, when forming the diffusion region 143, trenches for the source and drain regions are masked off, and vice versa. Note that no such diffusion or source or drain region is grown within the trenches 166a, 166b. For example, these trenches 166a, 166b may be masked off when forming the various regions 143, 134, 138a, 138b.

Referring again to FIG. 4, the method 400 then proceeds from 416 to 420, where dummy gate structures 511 are removed, and the nanoribbons 104 are released by removing the layers of sacrificial materials 504, as illustrated in FIG. 5F. In an example, the dummy gate materials (such as dummy gate dielectric and dummy gate electrodes 520) are removed via an etch process that is selective to the gate spacers 148 and inner gate spacers 145 and other non-gate materials exposed during channel and gate processing. Removing the dummy gate electrode between the gate spacers exposes the channel region of the fin. For example, a polycrystalline silicon dummy gate electrode can be removed using a wet etch process (e.g., nitric acid/hydrofluoric acid), an anisotropic dry etch, or other suitable etch process, as will be appreciated. At this stage of processing, the layer stack of alternating layers of channel material and sacrificial material is exposed in the channel region.

The sacrificial material 504 in the layer stack can then be removed by etch processing, to release the nanoribbons 104, in accordance with some embodiments. Etching the sacrificial material 504 may be performed using any suitable wet or dry etching process such that the etch process selectively removes the sacrificial material and leaves intact the channel material. In one embodiment, the sacrificial material is silicon germanium (SiGe) and the channel material is electronic grade silicon (Si). For example, a gas-phase etch using an oxidizer and hydrofluoric acid (HF) has shown to selectively etch SiGe in SiGe/Si layer stacks. In another embodiment, a gas-phase chlorine trifluoride (ClF3) etch is used to remove the sacrificial SiGe material. The etch chemistry can be selected based on the germanium concentration, nanoribbon dimensions, and other factors, as will be appreciated. After removing the SiGe sacrificial material, the resulting channel region includes silicon nanoribbons extending from corresponding diffusion or source or drain region, where at least one end of each nanoribbon 104 (e.g., silicon) contacts a corresponding diffusion or source or drain region.

Referring again to FIG. 4, the method 400 then proceeds from 420 to 424, where the various final gate structures 125 including gate electrodes 122 and gate dielectric 123 are formed, as illustrated in FIG. 5G. Note that the gate dielectric 123 is not separately labelled in FIG. 5G, and FIG. 5G shows the gate electrodes 122. However, the expanded view of a portion 119 of FIG. 1A illustrates and labels the gate dielectric 123.

Referring again to the method 400 of FIG. 4, the method 400 proceeds from 424 to 428. At 428, a general integrated circuit (IC) is completed, as desired, in accordance with some embodiments. Such additional processing to complete an IC may include forming various contacts 147a, 147b, 147c, 147d, 147e, and depositing dielectric material 165, as illustrated in FIG. 5H, and may also include back-end or back-end-of-line (BEOL) processing to form one or more metallization layers and/or to interconnect the transistor devices formed, for example. Any other suitable processing may be performed, as will be apparent in light of this disclosure.

Note that the processes in method 400 are shown in a particular order for ease of description. However, one or more of the processes may be performed in a different order or may not be performed at all (and thus be optional), in accordance with some embodiments. Numerous variations on method 400 and the techniques described herein will be apparent in light of this disclosure.

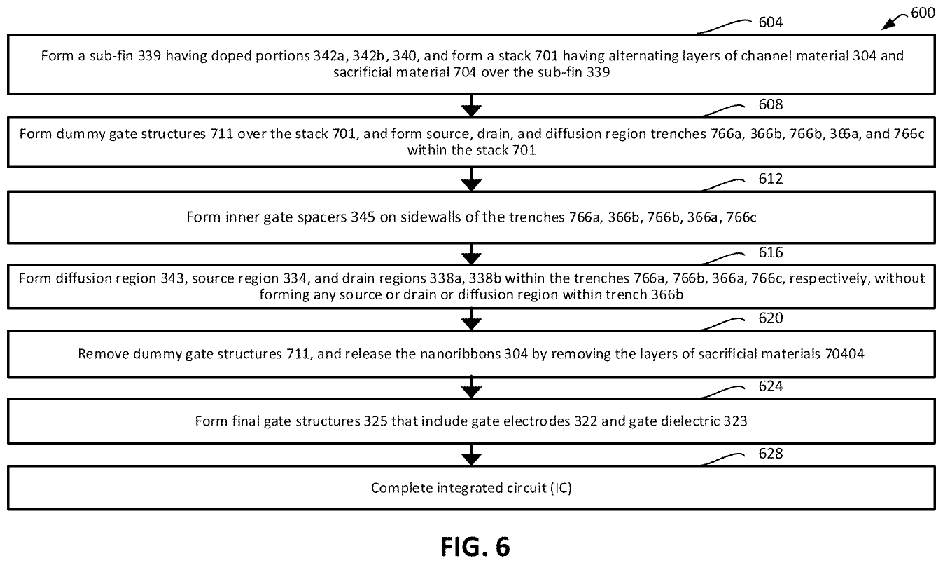

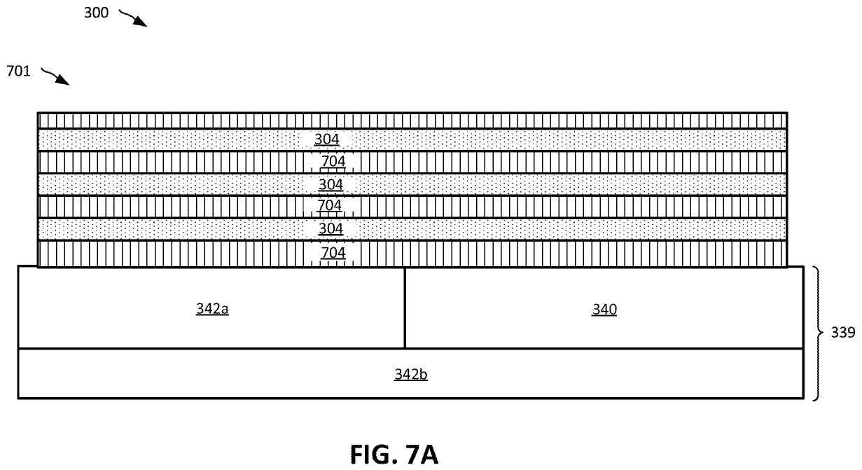

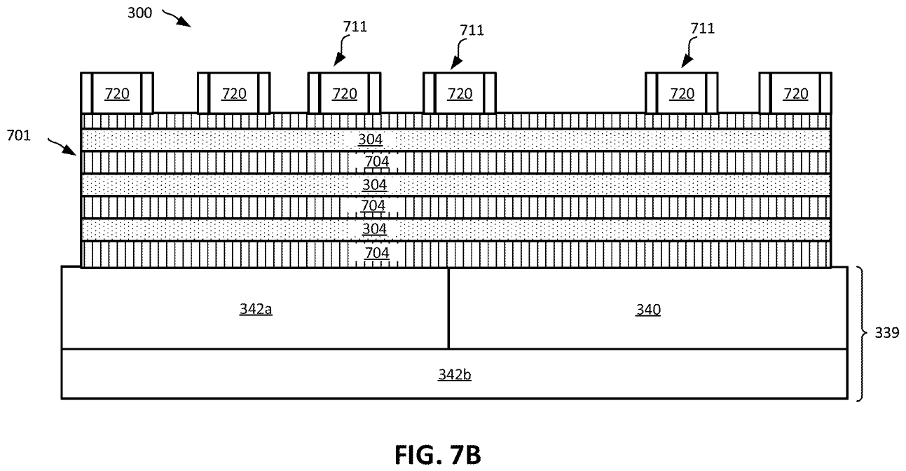

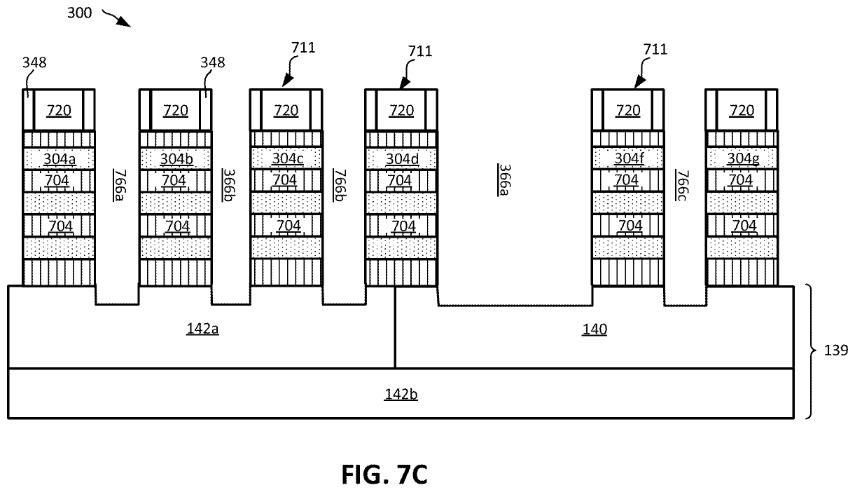

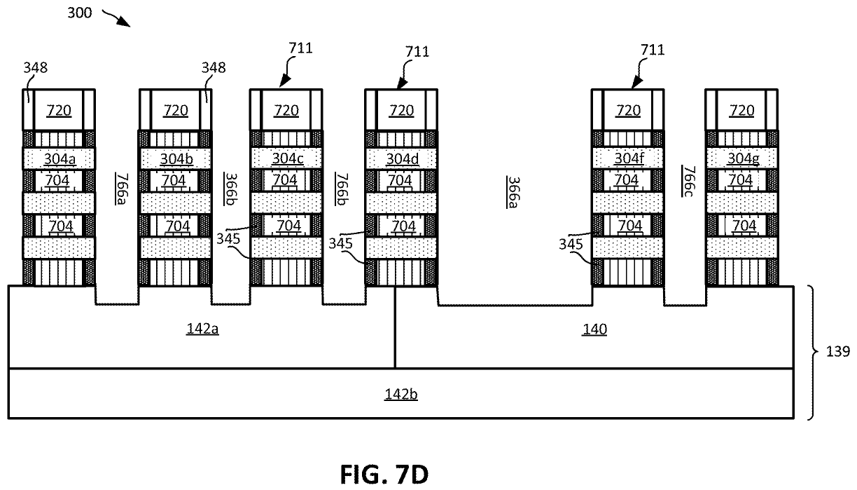

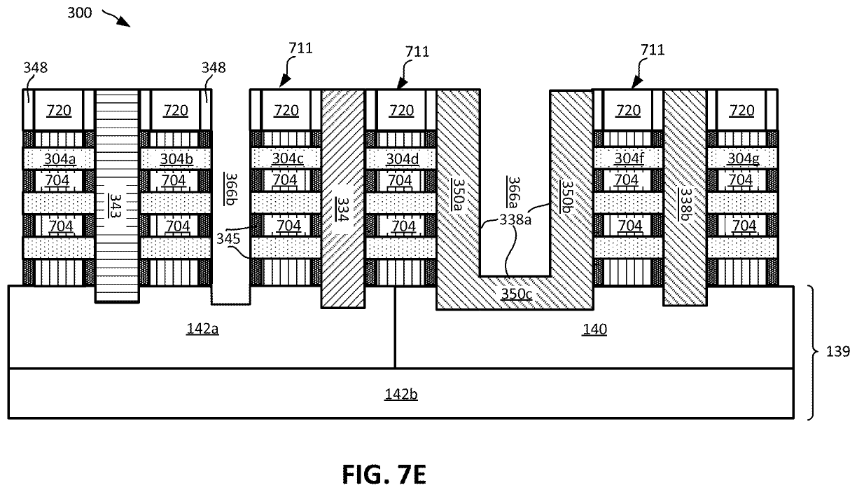

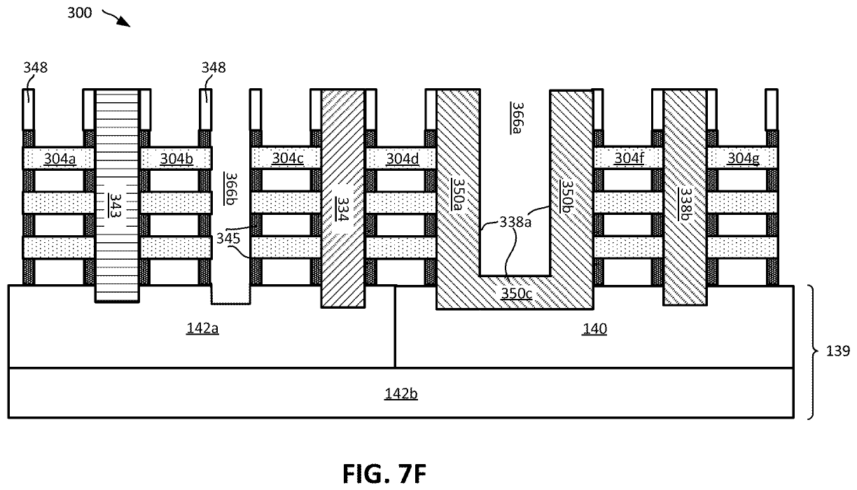

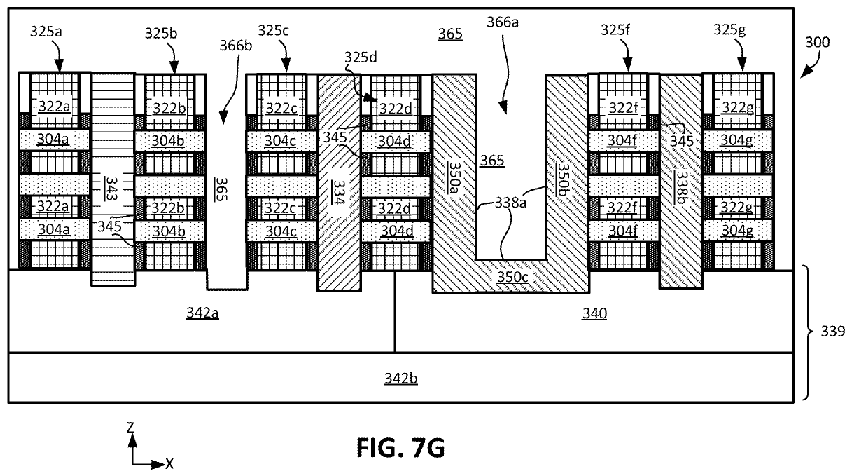

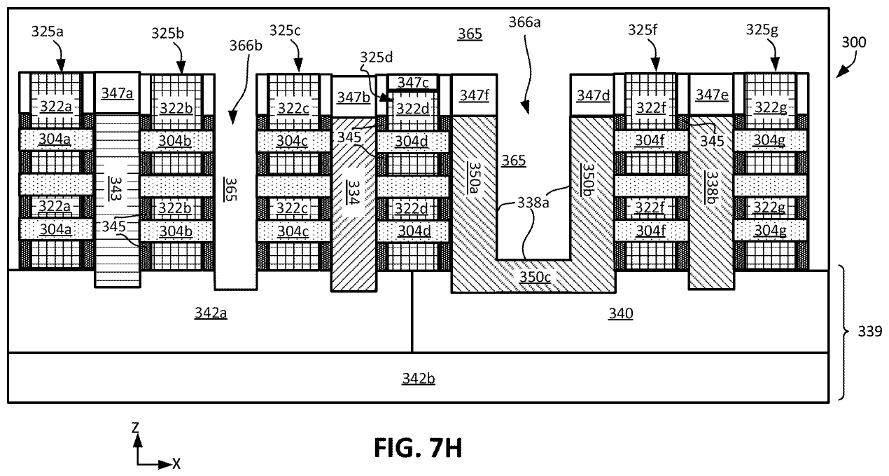

FIG. 6 illustrates a flowchart depicting a method 600 of forming another integrated circuit structure (such as the integrated circuit structure 300 of FIGS. 3A-3D), in accordance with an embodiment of the present disclosure. FIGS. 7A, 7B, 7C, 7D, 7E, 7F, 7G, and 711 collectively illustrate cross-sectional views of the integrated circuit structure in various stages of processing in the methodology 600 of FIG. 6, in accordance with an embodiment of the present disclosure. FIGS. 6 and 7A-7G will be discussed in unison.

Referring to FIG. 6, the method 600 includes, at 604, from frontside of the integrated circuit chip, forming a sub-fin 339 having appropriately doped portions 342a, 342b, 340, and forming a stack 701 having alternating layers of channel material 304 and sacrificial material 704 over the sub-fin 339, as illustrated in FIG. 7A. In an example, the process 604 is at least in part similar to the process 404 discussed above with respect to method 400.

Referring again to FIG. 6, the method 600 then proceeds from 604 to 608, which includes forming dummy gate structures 711 over the stack 701, and forming trenches 766a, 366b, 766b, 366a, and 766c within portions of the stack 701 not covered by the dummy gate structures 711, as illustrated in FIGS. 7B and 7C. In an example, the process 608 of forming dummy gates and trenches is at least in part similar to the process 408 discussed above with respect to method 400. In an example, each dummy gate structure 711 comprises dummy gate oxide (not labelled in FIG. 7B), dummy gate electrode 720 (e.g., comprising polysilicon, for example), and gate spaces 348. The dummy gates are formed in positions where the final metal gates are to be eventually formed for the structure 300. Note that formation of one dummy gate (e.g., between the second and third dummy gates 711 from the left) is skipped, resulting in irregular pitch of the dummy gates 711, as illustrated in FIG. 7B. This in turn results in a wider trench 366a, compared to the other trenches, as illustrated in FIG. 7C. For example, formation of the dummy gate maybe skipped by masking the area between the second and third dummy gates (from the left) during the dummy gate formation processes, and then later removing the mask.

Referring again to FIG. 6, the method 600 then proceeds from 608 to 612, where inner gate spacers 345 are formed on sidewalls of the trenches 766a, 366b, 766b, 366a, 766c, as illustrated in FIG. 7D. In an example, the process 612 of forming inner gate spacers is at least in part similar to the process 412 discussed above with respect to method 400.

Referring again to FIG. 6, the method 600 then proceeds from 612 to 616, where diffusion region 343, source region 334, and drain regions 338a, 38b are formed (e.g., grown epitaxially) within the trenches 766a, 766b, 366a, and 766c, respectively, without forming any source or drain or diffusion region within trench 366a, as illustrated in FIG. 7E. In an example, the process 616 of forming the diffusion, source and drain regions is at least in part similar to the process 416 discussed above with respect to method 400. For example, the regions 343, 334, 338a, 338b are formed epitaxially within the corresponding trenches. In some embodiments, these regions may include any suitable doping scheme, such as including suitable n-type and/or p-type dopant (e.g., in a concentration in the range of 1E16 to 1E22 atoms per cubic cm), as discussed above. Dopant types of various diffusion regions have been discussed herein above. Note that the drain region 338a within the trench 366a is grown epitaxially from both side walls and the bottom surface of the trench 366a, resulting in the vertical end portions 350a, 350b and intermediate horizontal portion 350c, e.g., the “U” shape of the drain region 338a, as illustrated in FIG. 7E.

Referring again to FIG. 6, the method 600 then proceeds from 616 to 620, where dummy gate structures 711 are removed, and the nanoribbons 304 are released by removing the layers of sacrificial materials 704, as illustrated in FIG. 7F. In an example, the process 620 of removing the dummy gates and releasing the nanoribbons is at least in part similar to the process 420 discussed above with respect to method 400.

Referring again to FIG. 6, the method 600 then proceeds from 620 to 624, where the various final gate structures 325 including gate electrodes 322 and gate dielectric 323 are formed, as illustrated in FIG. 7G. In an example, the process 624 of forming the final gate structure is at least in part similar to the process 424 discussed above with respect to method 400.

Referring again to the method 600 of FIG. 6, the method 600 proceeds from 624 to 628. At 628, a general IC is completed, as desired, in accordance with some embodiments. Such additional processing to complete an IC may include forming various contacts 347a, 347b, 347c, 347d, 347e, 347f, and depositing dielectric material 365, as illustrated in FIG. 7H, and may also include back-end or back-end-of-line (BEOL) processing to form one or more metallization layers and/or to interconnect the transistor devices formed, for example. Any other suitable processing may be performed, as will be apparent in light of this disclosure.

Note that the processes in method 600 are shown in a particular order for ease of description. However, one or more of the processes may be performed in a different order or may not be performed at all (and thus be optional), in accordance with some embodiments. Numerous variations on method 600 and the techniques described herein will be apparent in light of this disclosure.

Example System

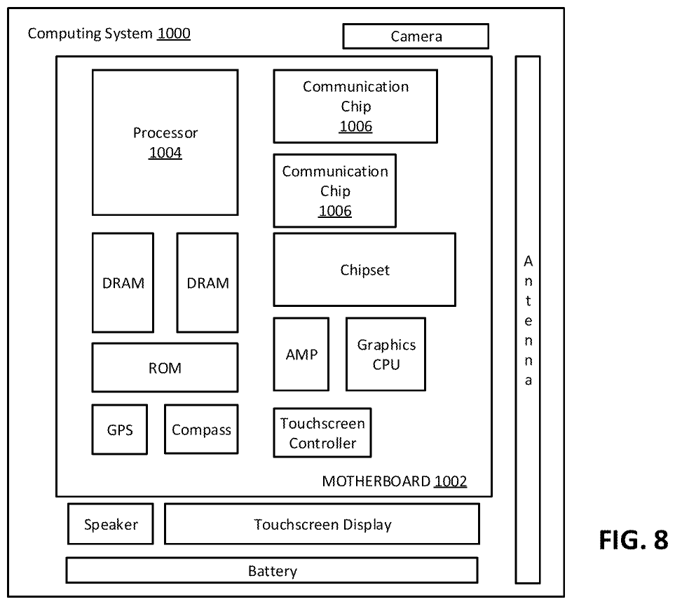

FIG. 8 illustrates a computing system 1000 implemented with integrated circuit structures (such as the structures 100 and 300 illustrated in FIGS. 1A-3D) formed using the techniques disclosed herein, in accordance with some embodiments of the present disclosure. As can be seen, the computing system 1000 houses a motherboard 1002. The motherboard 1002 may include a number of components, including, but not limited to, a processor 1004 and at least one communication chip 1006, each of which can be physically and electrically coupled to the motherboard 1002, or otherwise integrated therein. As will be appreciated, the motherboard 1002 may be, for example, any printed circuit board, whether a main board, a daughterboard mounted on a main board, or the only board of system 1000, etc.

Depending on its applications, computing system 1000 may include one or more other components that may or may not be physically and electrically coupled to the motherboard 1002. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1000 may include one or more integrated circuit structures or devices formed using the disclosed techniques in accordance with an example embodiment. In some embodiments, multiple functions can be integrated into one or more chips (e.g., for instance, note that the communication chip 1006 can be part of or otherwise integrated into the processor 1004).

The communication chip 1006 enables wireless communications for the transfer of data to and from the computing system 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 of the computing system 1000 includes an integrated circuit die packaged within the processor 1004. In some embodiments, the integrated circuit die of the processor includes onboard circuitry that is implemented with one or more integrated circuit structures or devices formed using the disclosed techniques, as variously described herein. The term “processor” may refer to any device or portion of a device that processes, for instance, electronic data from registers and/or memory to transform that electronic data into other electronic data that may be stored in registers and/or memory.

The communication chip 1006 also may include an integrated circuit die packaged within the communication chip 1006. In accordance with some such example embodiments, the integrated circuit die of the communication chip includes one or more integrated circuit structures or devices formed using the disclosed techniques as variously described herein. As will be appreciated in light of this disclosure, note that multi-standard wireless capability may be integrated directly into the processor 1004 (e.g., where functionality of any chips 1006 is integrated into processor 1004, rather than having separate communication chips). Further note that processor 1004 may be a chip set having such wireless capability. In short, any number of processor 1004 and/or communication chips 1006 can be used. Likewise, any one chip or chip set can have multiple functions integrated therein.

In various implementations, the computing system 1000 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device or system that processes data or employs one or more integrated circuit structures or devices formed using the disclosed techniques, as variously described herein. Note that reference to a computing system is intended to include computing devices, apparatuses, and other structures configured for computing or processing information.

### Further Example Embodiments

The following examples pertain to further embodiments, from which numerous permutations and configurations will be apparent.

Example 1. An integrated circuit structure, comprising: a sub-fin; a source region in contact with a first portion of the sub-fin; a drain region in contact with a second portion of the sub-fin; a body comprising semiconductor material above the sub-fin, the body extending laterally between the source region and the drain region; and a gate structure on the body and comprising (i) a gate electrode, and (ii) a gate dielectric between the gate electrode and the body; wherein a first distance between the drain region and the gate electrode is at least two times a second distance between the source region and the gate electrode, the first and second distances measured in a same horizontal plane that runs in a direction parallel to the body.

Example 2. The integrated circuit structure of example 1, wherein the first portion of the sub-fin is doped with one of a p-type or an n-type dopant, and wherein (i) the second portion of the sub-fin, (ii) the source region, and (iii) the drain region are doped with the other of the p-type or the n-type dopant.

Example 3. The integrated circuit structure of example 2, wherein: the first and second portions of the sub-fin are laterally adjacent to each other; a first section of the body, which is nearer to the source region, is above the first portion of the sub-fin; and a second section of the body, which is farther from the source region and laterally adjacent to the first section of the body, is above the second portion of the sub-fin.

Example 4. The integrated circuit structure of any one of examples 1-2, wherein: the first portion of the sub-fin is doped with p-type dopant; and the second portion of the sub-fin, the source region, and the drain region are doped with n-type dopant.

Example 5. The integrated circuit structure of any one of examples 1-4, wherein there is no intervening source or drain region between the source region and the drain region.

Example 6. The integrated circuit structure of any one of examples 1-5, wherein the body is a first body, and wherein the integrated circuit structure further comprises: a diffusion region, which is neither a source region nor a drain region, in contact with the first portion of the sub-fin, wherein the source region, the drain region, and the second portion of the sub-fin are doped with one of p-type or n-type dopant, and wherein the diffusion region and the first portion of the sub-fin are doped with the other of p-type or n-type dopant; a second body extending laterally from the diffusion region toward the source and drain regions, such that a first end portion of the second body is in contact with the diffusion region, and a second end portion of the second body is not in contact with any source or drain region; and a third body extending laterally from the diffusion region and away the source and drain regions, such that a first end portion of the third body is in contact with the diffusion region, and a second end portion of the third body is not in contact with any source or drain region.

Example 7. The integrated circuit structure of example 6, wherein each of the first, second, and third bodies is a nanoribbon, a nanosheet, a nanowire, or a fin based structure.

Example 8. The integrated circuit structure of any one of examples 1-7, wherein the body extends laterally from the source region toward the drain region, such that a first end portion of the body is in contact with the source region, a middle portion of the body is in contact with the gate structure, and a second end portion of the body is not in contact with any source or drain region.

Example 9. The integrated circuit structure of example 8, further comprising: a first inner gate spacer wrapping around the first end portion of the body; and a second inner gate spacer wrapping around the second end portion of the body.

Example 10. The integrated circuit structure of any one of examples 1-9, wherein the body is a first body, and wherein the integrated circuit structure further comprises: a second body comprising semiconductor material above the sub-fin, the second body extending laterally between the source region and the drain region, wherein the second body extends from the drain region towards the source region, such that a first end portion of the second body is in contact with the drain region, and a second end portion of the second body is not in contact with any source or drain region.

Example 11. The integrated circuit structure of any one of examples 1-10, wherein the body is a first body, and wherein the integrated circuit structure further comprises: a second body comprising semiconductor material above the sub-fin, the second body extending laterally between the source region and the drain region, wherein the second body extends from the drain region towards the source region; and a structure comprising dielectric material laterally between and separating the second body and the first body.

Example 12. The integrated circuit structure of example 11, wherein an end portion of each of the first and second bodies is in contact with the structure comprising dielectric material.

Example 13. The integrated circuit structure of any one of examples 11-12, wherein the gate structure is a first gate structure, and wherein the integrated circuit structure further comprises: a second gate structure on a middle portion of the second body, wherein the second gate structure is electrically floating.

Example 14. The integrated circuit structure of any one of examples 1-13, further comprising one or more interconnect features to electrically couple the gate structure to the source region.

Example 15. The integrated circuit structure of any one of examples 1-14, wherein each of the gate structure and the source region are grounded, and the drain region is electrically coupled to an input/output (I/O) pin of the integrated circuit structure.

Example 16. The integrated circuit structure of any one of examples 1-15, wherein: the drain region includes (i) a first end portion, (ii) a second end portion, and (iii) an intermediate portion that conjoins a lower section of the first end portion and a lower section of the second end portion; each of the first and second end portions of the drain region is taller than the intermediate portion of the drain region; the second end portion of the drain region is laterally between the gate electrode and the first end portion of the drain region; and the first distance between the drain region and the gate electrode is measured between the first end portion of the drain region and the gate electrode.

Example 17. The integrated circuit structure of example 16, wherein the first end portion and the second end portion of the drain region extends vertically upwards from the second portion of the sub-fin, and the intermediate portion of the drain region is on the second portion of the sub-fin.

Example 18. The integrated circuit structure of any one of examples 16-17, further comprising dielectric material laterally between an upper section of the first end portion of the drain region and an upper section of the second end portion of the drain region.

Example 19. The integrated circuit structure of any one of examples 16-18, wherein the drain region is a first drain region, the body is a first body that extends from the source region to the second end portion of the first drain region, the gate structure is on a middle portion of the first body, and wherein the integrated circuit structure further comprises: a second drain region; and a second body that extends laterally from the first end portion of the first drain region to the second drain region.

Example 20. The integrated circuit structure of any one of examples 16-19, wherein: the body is a first body that extends from the source region to the second end portion of the drain region; and the integrated circuit structure comprises a second body extending laterally from the first end portion of the drain region and away from the source region.

Example 20. An integrated circuit structure, comprising: a sub-fin comprising (i) a first portion doped with a first type of dopant, and (ii) a second portion doped with a second type of dopant and laterally adjacent to the first portion, wherein the first type of dopant is one of a p-type or an n-type dopant, and wherein the second type of dopant is the other of the p-type or the n-type dopant; a source region doped with the second type of dopant, the source region in contact with the first portion of the sub-fin; and a drain region doped with the second type dopant, the drain region in contact with the second portion of the sub-fin that is also doped with the second type of dopant.

Example 21. The integrated circuit structure of example 20, wherein the first type of dopant is the p-type dopant, and the second type of dopant is the n-type dopant.

Example 22. The integrated circuit structure of any one of examples 20-21, further comprising: a body comprising semiconductor material above the sub-fin, the body extending laterally between the source region and the drain region; and a gate structure on the body and comprising (i) a gate electrode, and (ii) a gate dielectric between the gate electrode and the body; wherein a first distance between the drain region and the gate electrode is at least 2 nanometers (nm) more than a second distance between the source region and the gate electrode, the first and second distances measured in a same horizontal plane that runs in a direction parallel to the body.

Example 23. The integrated circuit structure of example 22, wherein the body includes: a first end portion in contact with the source region, the first end portion of the body above the first portion of the sub-fin; a second end portion opposite the first end portion, the second end portion of the body above the second portion of the sub-fin; and a middle portion laterally between the first and second end portions, the middle portion having (i) a first section that is above the first portion of the sub-fin, and (ii) a second section that is above the second portion of the sub-fin; wherein the body is one of a nanoribbon, a nanosheet, a nanowire, or a fin.

Example 24. A transistor structure circuit structure, comprising: a sub-fin comprising (i) a first portion comprising p-type dopant, and (ii) a second portion comprising n-type of dopant; a first source or drain region in contact with the first portion of the sub-fin, and a second source or drain region in contact with the second portion of the sub-fin; and a body comprising semiconductor material extending laterally between the first and second source or drain regions, the body having a first section and a laterally adjacent second section, wherein the first section of the body is above the first portion of the sub-fin, and the second section of the body is above the second portion of the sub-fin.

Example 25. The transistor structure of example 24, wherein the body is a nanoribbon, a nanosheet, a nanowire, or a fin.

Example 26. The transistor structure of any one of examples 24-25, wherein a first end portion of the first section of the body is in contact with the first source or drain region, and wherein the second section of the body is not in contact with any source or drain region.

Example 27. The transistor structure of any one of examples 24-25, wherein a first end portion of the first section of the body is in contact with the first source or drain region, and wherein the second section of the body is in contact with the second source or drain region.

Example 28. The transistor structure of any one of examples 24-27, wherein the second source or drain region comprises: a first vertical section extending vertically from the second portion of the sub-fin; a second vertical section extending vertically from the second portion of the sub-fin; and a horizontal section on the second portion of the sub-fin, the horizontal section conjoining a lower section of the first vertical section and a lower section of the second vertical section; wherein the transistor structure further comprises dielectric material laterally between an upper section of the first vertical section and an upper section of the second vertical section.

The foregoing description of example embodiments of the present disclosure has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto.

What is claimed is:

1. An integrated circuit structure, comprising:
a sub-fin;
a source region in contact with a first portion of the sub-fin;
a drain region in contact with a second portion of the sub-fin;
a body comprising semiconductor material above the sub-fin, the body extending laterally between the source region and the drain region; and
a gate structure on the body and comprising (i) a gate electrode, and (ii) a gate dielectric between the gate electrode and the body;
wherein a first distance between the drain region and the gate electrode is at least two times a second distance between the source region and the gate electrode, the first and second distances measured in a same horizontal plane that runs in a direction parallel to the body.

2. The integrated circuit structure of claim 1, wherein the first portion of the sub-fin is doped with one of a p-type or an n-type dopant, and wherein (i) the second portion of the sub-fin, (ii) the source region, and (iii) the drain region are doped with the other of the p-type or the n-type dopant.

3. The integrated circuit structure of claim 2, wherein:
the first and second portions of the sub-fin are laterally adjacent to each other;
a first section of the body, which is nearer to the source region, is above the first portion of the sub-fin; and
a second section of the body, which is farther from the source region and laterally adjacent to the first section of the body, is above the second portion of the sub-fin.

4. The integrated circuit structure of claim 1, wherein:
the first portion of the sub-fin is doped with p-type dopant; and
the second portion of the sub-fin, the source region, and the drain region are doped with n-type dopant.

5. The integrated circuit structure of claim 1, wherein there is no intervening source or drain region between the source region and the drain region.

6. The integrated circuit structure of claim 1, wherein the body is a first body, and wherein the integrated circuit structure further comprises:
a diffusion region, which is neither a source region nor a drain region, in contact with the first portion of the sub-fin, wherein the source region, the drain region, and the second portion of the sub-fin are doped with one of p-type or n-type dopant, and wherein the diffusion region and the first portion of the sub-fin are doped with the other of p-type or n-type dopant;
a second body extending laterally from the diffusion region toward the source and drain regions, such that a first end portion of the second body is in contact with the diffusion region, and a second end portion of the second body is not in contact with any source or drain region; and
a third body extending laterally from the diffusion region and away the source and drain regions, such that a first end portion of the third body is in contact with the diffusion region, and a second end portion of the third body is not in contact with any source or drain region.

7. The integrated circuit structure of claim 6, wherein each of the first, second, and third bodies is a nanoribbon, a nanosheet, a nanowire, or a fin based structure.

8. The integrated circuit structure of claim 1, wherein the body extends laterally from the source region toward the drain region, such that a first end portion of the body is in contact with the source region, a middle portion of the body is in contact with the gate structure, and a second end portion of the body is not in contact with any source or drain region.

9. The integrated circuit structure of claim 1, wherein the body is a first body, and wherein the integrated circuit structure further comprises:
a second body comprising semiconductor material above the sub-fin, the second body extending laterally between the source region and the drain region, wherein the second body extends from the drain region towards the source region; and
a structure comprising dielectric material laterally between and separating the second body and the first body.

10. The integrated circuit structure of claim 9, wherein an end portion of each of the first and second bodies is in contact with the structure comprising dielectric material.

11. The integrated circuit structure of claim 1, further comprising one or more interconnect features to electrically couple the gate structure to the source region, wherein each of the gate structure and the source region are grounded, and the drain region is electrically coupled to an input/output (I/O) pin of the integrated circuit structure.

12. The integrated circuit structure of claim 1, wherein:
the drain region includes (i) a first end portion, (ii) a second end portion, and (iii) an intermediate portion that conjoins a lower section of the first end portion and a lower section of the second end portion;
each of the first and second end portions of the drain region is taller than the intermediate portion of the drain region;
the second end portion of the drain region is laterally between the gate electrode and the first end portion of the drain region; and
the first distance between the drain region and the gate electrode is measured between the first end portion of the drain region and the gate electrode.

13. The integrated circuit structure of claim 12, wherein the first end portion and the second end portion of the drain region extends vertically upwards from the second portion of the sub-fin, and the intermediate portion of the drain region is on the second portion of the sub-fin.

14. The integrated circuit structure of claim 12, further comprising dielectric material laterally between an upper section of the first end portion of the drain region and an upper section of the second end portion of the drain region.

15. The integrated circuit structure of claim 12, wherein the drain region is a first drain region, the body is a first body that extends from the source region to the second end portion of the first drain region, the gate structure is on a middle portion of the first body, and wherein the integrated circuit structure further comprises:
a second drain region; and
a second body that extends laterally from the first end portion of the first drain region to the second drain region.

16. An integrated circuit structure, comprising:
a sub-fin comprising (i) a first portion doped with a first type of dopant, and (ii) a second portion doped with a second type of dopant and laterally adjacent to the first portion, wherein the first type of dopant is one of a p-type or an n-type dopant, and wherein the second type of dopant is the other of the p-type or the n-type dopant;
a source region doped with the second type of dopant, the source region in contact with the first portion of the sub-fin; and
a drain region doped with the second type dopant, the drain region in contact with the second portion of the sub-fin that is also doped with the second type of dopant.

17. The integrated circuit structure of claim 16, further comprising:
a body comprising semiconductor material above the sub-fin, the body extending laterally between the source region and the drain region; and
a gate structure on the body and comprising (i) a gate electrode, and (ii) a gate dielectric between the gate electrode and the body;
wherein a first distance between the drain region and the gate electrode is at least 2 nanometers (nm) more than a second distance between the source region and the gate electrode, the first and second distances measured in a same horizontal plane that runs in a direction parallel to the body;
wherein the body includes
a first end portion in contact with the source region, the first end portion of the body above the first portion of the sub-fin,
a second end portion opposite the first end portion, the second end portion of the body above the second portion of the sub-fin, and
a middle portion laterally between the first and second end portions, the middle portion having (i) a first section that is above the first portion of the sub-fin, and (ii) a second section that is above the second portion of the sub-fin; and
wherein the body is one of a nanoribbon, a nanosheet, a nanowire, or a fin.

18. A transistor structure circuit structure, comprising:
a sub-fin comprising (i) a first portion comprising p-type dopant, and (ii) a second portion comprising n-type of dopant;
a first source or drain region in contact with the first portion of the sub-fin, and a second source or drain region in contact with the second portion of the sub-fin; and
a body comprising semiconductor material extending laterally between the first and second source or drain regions, the body having a first section and a laterally adjacent second section, wherein the first section of the body is above the first portion of the sub-fin, and the second section of the body is above the second portion of the sub-fin.

19. The transistor structure of claim 18, wherein a first end portion of the first section of the body is in contact with the first source or drain region, and wherein the second section of the body is not in contact with any source or drain region.

20. The transistor structure of claim 18, wherein the second source or drain region comprises:
a first vertical section extending vertically from the second portion of the sub-fin;
a second vertical section extending vertically from the second portion of the sub-fin; and
a horizontal section on the second portion of the sub-fin, the horizontal section conjoining a lower section of the first vertical section and a lower section of the second vertical section;
wherein the transistor structure further comprises dielectric material laterally between an upper section of the first vertical section and an upper section of the second vertical section.
